(19) United States
(12) Patent Application Publication
(10) Pub. No.: US 2026/0123154 A1
(43) Pub. Date: Apr. 30, 2026

(54) DISPLAY DEVICE, ELECTRONIC DEVICE INCLUDING DISPLAY DEVICE, AND METHOD OF MANUFACTURING DISPLAY DEVICE

(71) Applicant: Samsung Display Co., LTD., Yongin-si (KR)

(72) Inventors: DONG GYU BAECK, Yongin-si (KR); MINSEOK KIM, Yongin-si (KR); SONGYI KIM, Yongin-si (KR); SUJIN KIM, Yongin-si (KR); YONGSEOK CHOI, Yongin-si (KR)

(21) Appl. No.: 19/004,648

(22) Filed: Dec. 30, 2024

(30) Foreign Application Priority Data
Jan. 26, 2024 (KR) 10-2024-0012452

(51) Int. Cl. H10H 29/85; H01L 25/075; H10H 29/01; H10H 29/851

(52) U.S. Cl. CPC H10H 29/8517; H10H 29/0361; H10H 29/0363; H10H 29/8511; H10W 90/00

(57) ABSTRACT

A display device include: a first light emitting element disposed in a first pixel area, a second light emitting element disposed in a second pixel area spaced apart from the first pixel area, a first color conversion layer disposed on the first light emitting element, a second color conversion layer disposed on the second light emitting element, a first color filter layer covering the first color conversion layer, a second color filter layer covering the second color conversion layer, and a third color filter layer disposed in a first non-light emitting area between the first pixel area and the second pixel area. The third color filter layer is configured to selectively transmit a color light different from color lights selectively transmitted by the first color conversion layer and the second color conversion layer.

This application claims priority to Korean Patent Application No. 10-2024-0012452, filed on Jan. 26, 2024, and all the benefits accruing therefrom under 35 U.S.C. § 119, the content of which in its entirety is herein incorporated by reference.

### BACKGROUND

### 1. Technical Field

Embodiments relate to a display device, an electronic device including the display device, and a method of manufacturing the display device. More particularly, embodiments relate to a display device including a color filter layer, an electronic device including the display device, and a method of manufacturing the display device.

### 2. Description of the Related Art

A display device is a device that displays an image for providing visual information to a user. Among display devices, an organic light emitting diode display has recently attracted attention.

In order to improve display quality, a display device including a display unit including a plurality of pixels and a color filter unit including a color filter layer and a color conversion layer has been proposed. The color conversion layer may convert a wavelength of light provided from the display unit. For example, the color conversion layer may include wavelength conversion particles such as quantum dots.

The color filter unit and the display unit may be separately manufactured and bonded to each other. In this case, manufacturing cost and manufacturing time of the display device may be excessively required. Accordingly, many studies have been conducted to reduce manufacturing cost and manufacturing time of the display device.

### SUMMARY

Embodiments provide a display device with improved quality.

Embodiments provide an electronic device including the display device.

Embodiments provide a method of manufacturing the display device.

A display device according to an embodiment includes a first light emitting element disposed in a first pixel area, a second light emitting element disposed in a second pixel area spaced apart from the first pixel area, a first color conversion layer disposed on the first light emitting element, a second color conversion layer disposed on the second light emitting element, a first color filter layer covering the first color conversion layer, a second color filter layer covering the second color conversion layer, and a third color filter layer disposed in a first non-light emitting area between the first pixel area and the second pixel area. The third color filter layer is configured to selectively transmit a color light different from color lights selectively transmitted by the first color conversion layer and the second color conversion layer.

In an embodiment, the first color filter layer may cover an upper surface of the first color conversion layer and a side surface of the first color conversion layer.

In an embodiment, the second color filter layer may cover an upper surface of the second color conversion layer and may extend to at least a portion of the first non-light emitting area between the first pixel area and the second pixel area.

In an embodiment, the display device may further include a third light emitting element disposed in a third pixel area spaced apart from the first pixel area and the second pixel area, and a light transmitting layer disposed on the third light emitting element. The third color filter layer may cover the light transmitting layer.

In an embodiment, a portion of the first color filter layer may cover a side surface of the light transmitting layer.

In an embodiment, the third color filter layer may be disposed in a portion of the first non-light emitting area between the first pixel area and the second pixel area.

In an embodiment, the third color filter layer may be disposed in at least a portion of a second non-light emitting area between the second pixel area and the third pixel area.

In an embodiment, the third color filter layer may be in contact with a side surface of the first color filter layer.

In an embodiment, the third color filter layer may cover an upper surface of the portion of the first color filter layer covering the side surface of the light transmitting layer.

In an embodiment, the second color filter layer may cover at least a portion of an upper surface of the third color filter layer.

In an embodiment, the first color filter layer may be disposed in an entirety of the first non-light emitting area.

In an embodiment, the first color filter layer may be disposed in an entirety of the second non-light emitting area.

In an embodiment, the first color filter layer may be in contact with a side surface of the second color conversion layer.

In an embodiment, the display device may further include a first low refractive index layer disposed between the first color conversion layer and the first color filter layer and a second low refractive index layer disposed between the second color conversion layer and the second color filter layer.

A display device according to an embodiment includes: a first light emitting element disposed in a first pixel area, a second light emitting element disposed in a second pixel area spaced apart from the first pixel area, a third light emitting element disposed in a third pixel area spaced apart from the first pixel area and the second pixel area, a first color conversion layer disposed on the first light emitting element, a second color conversion layer disposed on the second light emitting element, a light transmitting layer disposed on the third light emitting element, a first color filter layer covering an upper surface of the first color conversion layer, a side surface of the second color conversion layer, and a side surface of the light transmitting layer, a second color filter layer covering a side surface of the first color conversion layer, an upper surface of the second color conversion layer, and a side surface of the light transmitting layer, and a third color filter layer covering an upper surface of the light transmitting layer.

In an embodiment, the third color filter layer may further be disposed in a first non-light emitting area between the first pixel area and the second pixel area.

In an embodiment, the third color filter layer may cover a portion of the second color filter layer covering the side surface of the first color conversion layer.

In an embodiment, the third color filter layer may further be disposed in a second non-light emitting area between the second pixel area and the third pixel area.

In an embodiment, the third color filter layer may cover a portion of the first color filter layer covering the side surface of the second color conversion layer.

In an embodiment, the third color filter layer may cover a side surface of a portion of the first color filter layer covering the upper surface of the first color conversion layer and a side surface of a portion of the second color filter layer covering the upper surface of the second color conversion layer.

In an embodiment, the third color filter layer may cover an upper surface of a portion of the first color filter layer covering the side surface of the light transmitting layer and an upper surface of a portion of the second color filter layer covering the side surface of the light transmitting layer.

A method of manufacturing a display device according to an embodiment includes forming a first light emitting element in a first pixel area, forming a second light emitting element in a second pixel area spaced apart from the first pixel area, forming a third light emitting element in a third pixel area spaced apart from the first pixel area and the second pixel area, forming a first color conversion layer on the first light emitting element, forming a second color conversion layer on the second light emitting element, forming a light transmitting layer on the third light emitting element, forming a first color filter layer covering the first color conversion layer, forming a second color filter layer covering the second color conversion layer, and forming a third color filter layer covering the light transmitting layer and disposed in a first non-light emitting area between the first pixel area and the second pixel area.

In an embodiment, the forming of the first color filter layer may include: forming a first preliminary color filter layer covering the first color conversion layer, the second color conversion layer, and the light transmitting layer; and removing a portion of the first preliminary color filter layer to form the first color filter layer, which covers a side surface of the light transmitting layer, an upper surface of the first color conversion layer, and a side surface of the first color conversion layer.

In an embodiment, the forming of the second color filter layer may include: forming a second preliminary color filter layer covering the first color conversion layer, the second color conversion layer, and the light transmitting layer; and removing a portion of the second preliminary color filter layer to form the second color filter layer, which covers an upper surface of the second color conversion layer.

In an embodiment, the forming of the third color filter layer may include: forming a third preliminary color filter layer covering the first color conversion layer, the second color conversion layer, and the light transmitting layer; and removing a portion of the third preliminary color filter layer to form the third color filter layer, which covers the light transmitting layer, and is disposed in the first non-light emitting area between the first pixel area and the second pixel area and a second non-light emitting area between the second pixel area and the third pixel area.

In an embodiment, the forming of the third color filter layer may be performed before the forming the second color filter layer.

An electronic device according to an embodiment includes a first light emitting element disposed in a first pixel area, a second light emitting element disposed in a second pixel area spaced apart from the first pixel area, a first color conversion layer disposed on the first light emitting element, a second color conversion layer disposed on the second light emitting element, a first color filter layer covering the first color conversion layer, a second color filter layer covering the second color conversion layer, a third color filter layer disposed in a first non-light emitting area between the first pixel area and the second pixel area, and a memory device configured to store data. The third color filter layer is configured to selectively transmit a color light different from color lights selectively transmitted by the first color conversion layer and the second color conversion layer.

A display device according to an embodiment may include a first light emitting element disposed in a first pixel area, a second light emitting element disposed in a second pixel area spaced apart from the first pixel area, a first color conversion layer disposed on the first light emitting element, a second color conversion layer disposed on the second light emitting element, a first color filter layer covering the first color conversion layer, and a second color filter layer covering the second color conversion layer.

Accordingly, color mixing between adjacent pixel areas may be effectively prevented. In addition, since a separate bank layer is not disposed between adjacent pixel areas, the pixel area may have a sufficient size. In addition, manufacturing cost and manufacturing time of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a cross-sectional view of the display device of FIG. 1 taken along line I-I′.

FIG. 3 is a cross-sectional view illustrating an example of an X-Y portion of FIG. 2.

FIG. 4 is a cross-sectional view illustrating another example of an X-Y portion of FIG. 2.

FIG. 5 is a cross-sectional view illustrating still another example of an X-Y portion of FIG. 2.

FIGS. 6, 7, 8, 9, 10, 11, 12, 13, and 14 are cross-sectional views illustrating a method of manufacturing the display device of FIG. 2.

FIG. 15 is a cross-sectional view illustrating a display device according to another embodiment.

FIG. 16 is a cross-sectional view illustrating an X′-Y′ portion of FIG. 15.

FIGS. 17, 18, 19, 20, 21, 22 and 23 are cross-sectional views illustrating a method of manufacturing the display device of FIG. 15.

FIG. 24 is a block diagram illustrating an electronic device according to embodiments.

FIG. 25 is a diagram illustrating an example in which the electronic device of FIG. 24 is implemented as a smart phone.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, display devices in accordance with embodiments will be described in more detail with reference to the accompanying drawings. The same reference numerals are used for the same components in the drawings, and redundant descriptions of the same components will be omitted.

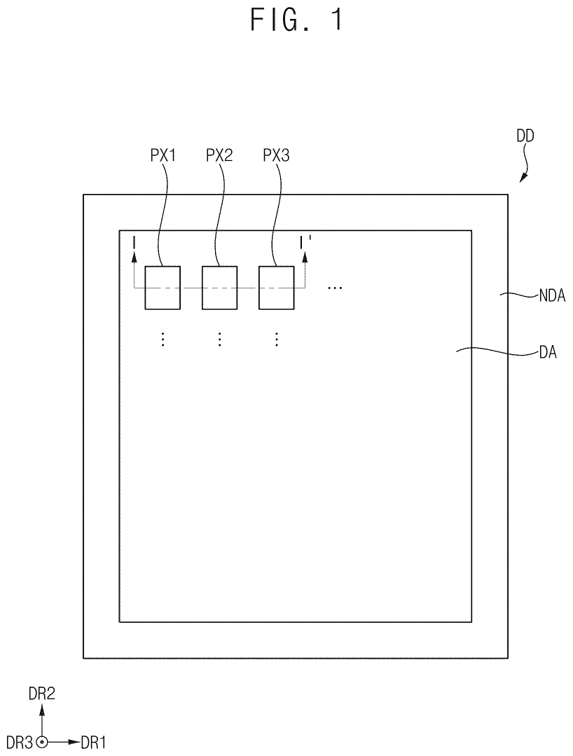

FIG. 1 is a plan view illustrating a display device according to an embodiment.

Referring to FIG. 1, a display device DD according to an embodiment may include a display area DA and a non-display area NDA.

A plurality of pixel areas may be disposed in the display area DA. For example, a first pixel area PX1, a second pixel area PX2, and a third pixel area PX3 may be disposed in the display area DA. Each of the plurality of pixel areas may emit light. For example, the first pixel area PX1 may emit first light, the second pixel area PX2 may emit second light, and the third pixel area PX3 may emit third light. For example, the first light may be red light, the second light may be green light, and the third light may be blue light. However, this disclosure is not limited thereto. For another example, the first light may be green light, the second light may be red light, and the third light may be blue light.

The plurality of pixel areas may be repeatedly arranged in a first direction DR1 and a second direction DR2 crossing the first direction DR1. For example, the second pixel area PX2 may be spaced apart from the first pixel area PX1 in the first direction DR1. In addition, the third pixel area PX3 may be spaced apart from the second pixel area PX2 in the first direction DR1.

The non-display area NDA may be disposed around the display area DA. For example, the non-display area NDA may surround at least a portion of the display area DA. A driver may be disposed in the non-display area NDA. The driver may provide signals or voltages to the plurality of pixel areas. For example, the driver may include a data driver, a gate driver, and/or the like. The non-display area NDA may not display an image.

In the present specification, the first direction DR1 and the second direction DR2 crossing the first direction DR1 may be defined. For example, the second direction DR2 may be perpendicular to the first direction DR1. However, this disclosure is not limited thereto, and the second direction DR2 may form an acute angle or an obtuse angle with the first direction DR1. In addition, a third direction DR3 crossing a plane formed by the first direction DR1 and second direction DR2 may be defined. For example, the third direction DR3 may be perpendicular to the plane formed by the first direction DR1 and second direction DR2. However, this disclosure is not limited thereto, and the third direction DR3 may form an acute angle or an obtuse angle with the plane formed by the first direction DR1 and second direction DR2.

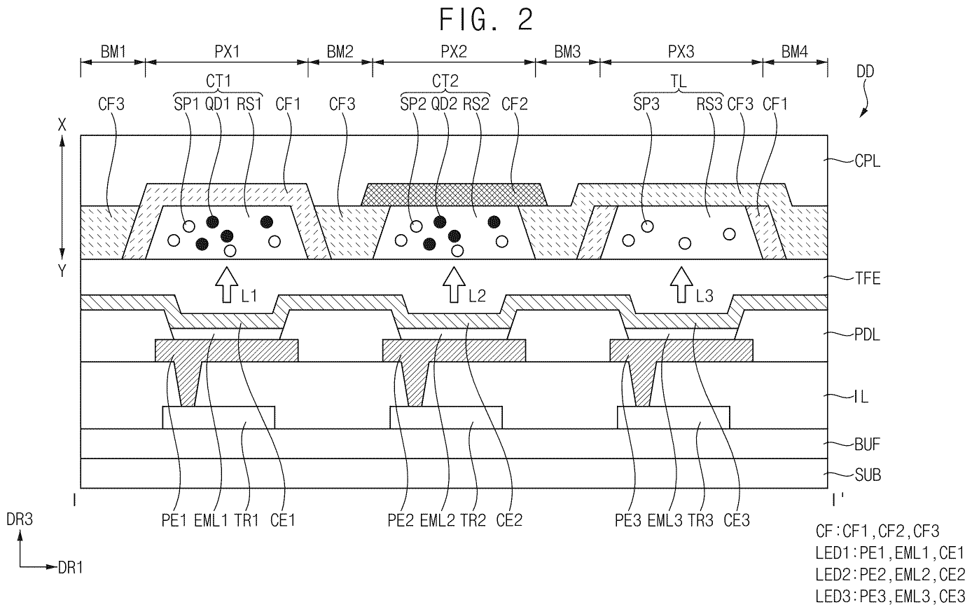

FIG. 2 is a cross-sectional view of the display device of FIG. 1 taken along line I-I′.

Referring to FIG. 2, the display device DD according to an embodiment may include a substrate SUB, a buffer layer BUF, an insulating layer IL, a first transistor TR1, a second transistor TR2, a third transistor TR3, a first light emitting element LED1, a second light emitting element LED2, a third light emitting element LED3, a pixel defining layer PDL, an encapsulation layer TFE, a color filter layer CF, a first color conversion layer CT1, a second color conversion layer CT2, a light transmitting layer TL, and a capping layer CPL.

The first light emitting element LED1 may include a first pixel electrode PE1, a first light emitting layer EML1, and a first common electrode CE1. The second light emitting element LED2 may include a second pixel electrode PE2, a second light emitting layer EML2, and a second common electrode CE2. The third light emitting element LED3 may include a third pixel electrode PE3, a third light emitting layer EML3, and a third common electrode CE3.

The first transistor TR1 may include a first active pattern, a first gate electrode, a first source electrode, and a first drain electrode. The second transistor TR2 may include a second active pattern, a second gate electrode, a second source electrode, and a second drain electrode. The third transistor TR3 may include a third active pattern, a third gate electrode, a third source electrode, and a third drain electrode.

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like.

Alternatively, the substrate SUB may include a quartz substrate (e.g., a synthetic quartz substrate, a fluorine-doped quartz substrate), a calcium fluoride substrate, a sodalime glass substrate, a non-alkali glass substrate, or the like. These materials may be used alone or in combination with each other.

The buffer layer BUF may be disposed on the substrate SUB. The buffer layer BUF may prevent metal atoms or impurities from diffusing from the substrate SUB to the first transistor TR1, the second transistor TR2, and the third transistor TR3. In addition, the buffer layer BUF can improve flatness of a surface of the substrate SUB when the surface of the substrate SUB is not uniform.

For example, the buffer layer BUF may include an inorganic material such as silicon oxide, silicon nitride, silicon oxynitride, or the like. These materials may be used alone or in combination with each other.

For example, the buffer layer BUF may include an inorganic material such as silicon oxide, silicon nitride, silicon carbide, silicon oxynitride, silicon oxycarbide, or the like. These materials may be used alone or in combination with each other.

The first transistor TR1, the second transistor TR2, and the third transistor TR3 may be disposed on the buffer layer BUF. For example, the first transistor TR1 may be disposed in at least a portion of the first pixel area PX1, the second transistor TR2 may be disposed in at least a portion of the second pixel area PX2, and the third transistor TR3 may be disposed in at least a portion of the third pixel area PX3.

For example, each of the first transistor TR1, the second transistor TR2, and the third transistor TR3 may include polycrystalline silicon or a metal oxide semiconductor.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The insulating layer IL may be disposed on the buffer layer BUF. The insulating layer IL may cover the first transistor TR1, the second transistor TR2, and the third transistor TR3. For example, the insulating layer IL may include at least one inorganic insulating layer and at least one organic insulating layer.

For example, the inorganic insulating layer may include silicon oxide, silicon nitride, silicon carbide, silicon oxynitride, silicon oxycarbide, or the like. These materials may be used alone or in combination with each other.

In addition, the organic insulating layer may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The first pixel electrode PE1, the second pixel electrode PE2, and the third pixel electrode PE3 may be disposed on the insulating layer IL. The first pixel electrode PE1 may be disposed in the first pixel area PX1, the second pixel electrode PE2 may be disposed in the second pixel area PX2, and the third pixel electrode PE3 may be disposed in the third pixel area PX3.

The first pixel electrode PE1 may be connected to the first transistor TR1 through a first contact hole formed by removing a portion of the insulating layer IL. The second pixel electrode PE2 may be connected to the second transistor TR2 through a second contact hole formed by removing a portion of the insulating layer IL. The third pixel electrode PE3 may be connected to the third transistor TR3 through a third contact hole formed by removing a portion of the insulating layer IL.

For example, each of the first pixel electrode PE1, the second pixel electrode PE2, and the third pixel electrode PE3 may include a metal, an alloy, a metal nitride, a conductive metal oxide, a transparent conductive material, or the like. These materials may be used alone or in combination with each other.

For example, the first pixel electrode PE1 may operate as an anode of the first light emitting element LED1. The second pixel electrode PE2 may operate as an anode of the second light emitting element LED2. The third pixel electrode PE3 may operate as an anode of the third light emitting element LED3.

The pixel defining layer PDL may be disposed on the insulating layer IL, the first pixel electrode PE1, the second pixel electrode PE2, and the third pixel electrode PE3. For example, the pixel defining layer PDL may be disposed in a first non-light emitting area BM1, a second non-light emitting area BM2, a third non-light emitting area BM3, and a fourth non-light emitting area BM4.

The pixel defining layer PDL may cover side portions of each of the first pixel electrode PE1, the second pixel electrode PE2, and the third pixel electrode PE3. In addition, the pixel defining layer PDL may expose an upper surface of each of the first pixel electrode PE1, the second pixel electrode PE2, and the third pixel electrode PE3.

For example, the pixel defining layer PDL may include an organic material and/or an inorganic material. In an embodiment, the pixel defining layer PDL may include an organic material. For example, the pixel defining layer PDL may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The second non-light emitting area BM2 may be disposed between the first pixel area PX1 and the second pixel area PX2. The second non-light emitting area BM2 may be spaced apart from the first non-light emitting area BM1 with the first pixel area PX1 interposed therebetween. The third non-light emitting area BM3 may be disposed between the second pixel area PX2 and the third pixel area PX3. The third non-light emitting area BM3 may be spaced apart from the second non-light emitting area BM2 with the second pixel area PX2 interposed therebetween. In addition, the third non-light emitting area BM3 may be spaced apart from the fourth non-light emitting area BM4 with the third pixel area PX3 interposed therebetween. The non-light emitting areas BM1, BM2, and BM3 do not include the color conversion layer CT1 and CT2 and the light transmitting layer TL.

The first light emitting layer EML1 may be disposed on the first pixel electrode PE1. For example, the first light emitting layer EML1 may be disposed in the first pixel area PX1. The second light emitting layer EML2 may be disposed on the second pixel electrode PE2. For example, the second light emitting layer EML2 may be disposed in the second pixel area PX2. The third light emitting layer EML3 may be disposed on the third pixel electrode PE3. For example, the third light emitting layer EML3 may be disposed in the third pixel area PX3.

Holes provided in the first pixel electrode PE1 and electrons provided in the first common electrode CE1 may form first excitons in the first light emitting layer EML1. The first light emitting layer EML1 may emit light as the first excitons change from the excited state to the ground state.

Holes provided in the second pixel electrode PE2 and the electrons provided in the second common electrode CE2 may form second excitons in the second light emitting layer EML2. The second light emitting layer EML2 may emit light as the second excitons change from the excited state to the ground state.

Holes provided in the third pixel electrode PE3 and the electrons provided in the third common electrode CE3 may form third excitons in the third light emitting layer EML3. The third light emitting layer EML3 may emit light as the third excitons change from the excited state to the ground state.

The first common electrode CE1 may be disposed on the first light emitting layer EML1. For example, the first common electrode CE1 may be disposed in the first pixel area PX1. The second common electrode CE2 may be disposed on the second light emitting layer EML2. For example, the second common electrode CE2 may be disposed in the second pixel area PX2. The third common electrode CE3 may be disposed on the third light emitting layer EML3. For example, the third common electrode CE3 may be disposed in the third pixel area PX3.

In an embodiment, the first common electrode CE1 may be connected to the second common electrode CE2, and the second common electrode CE2 may be connected to the third common electrode CE3. That is, the first common electrode CE1, the second common electrode CE2, and the third common electrode CE3 may be integrally formed.

However, this disclosure is not limited thereto, and in another embodiment, the first common electrode CE1 may be separated from the second common electrode CE2, and the second common electrode CE2 may be separated from the third common electrode CE3.

For example, each of the first common electrode CE1, the second common electrode CE2, and the third common electrode CE3 may include a metal, an alloy, a metal nitride, a conductive metal oxide, a transparent conductive material, or the like. These materials may be used alone or in combination with each other.

For example, the first common electrode CE1 may operate as a cathode of the first light emitting element LED1. The second common electrode CE2 may operate as a cathode of the second light emitting element LED2. The third common electrode CE3 may operate as a cathode of the third light emitting element LED3.

The encapsulation layer TFE may be disposed on the first common electrode CE1, the second common electrode CE2, and the third common electrode CE3. The encapsulation layer TFE may prevent impurities, moisture, and the like from penetrating into the first light emitting element LED1, the second light emitting element LED2, and the third light emitting element LED3.

For example, the encapsulation layer TFE may include at least one inorganic encapsulation layer and at least one organic encapsulation layer. The inorganic encapsulation layer may include silicon oxide, silicon nitride, silicon oxynitride, or the like. These materials may be used alone or in combination with each other. The organic encapsulation layer may include a cured polymer material such as polyacrylate.

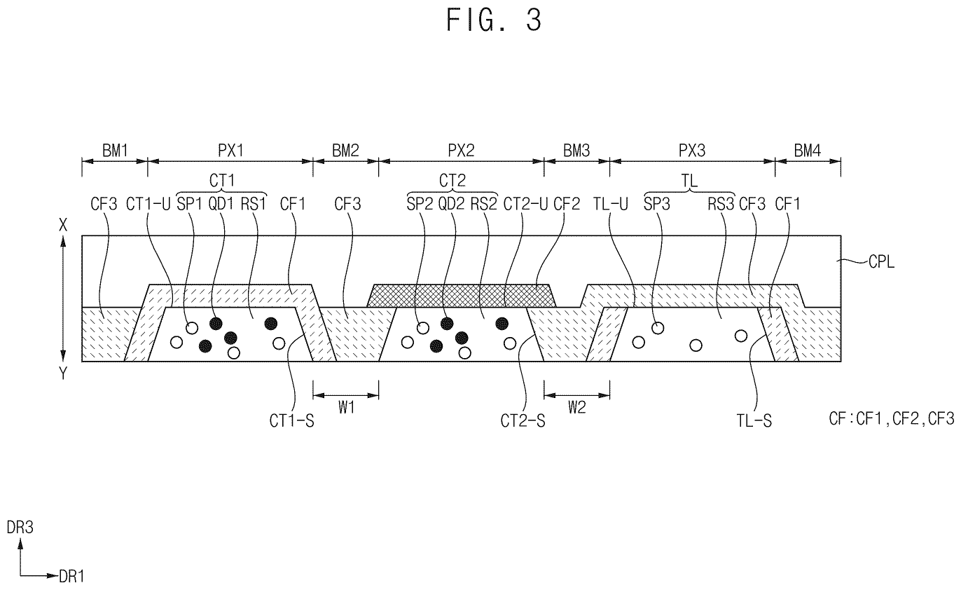

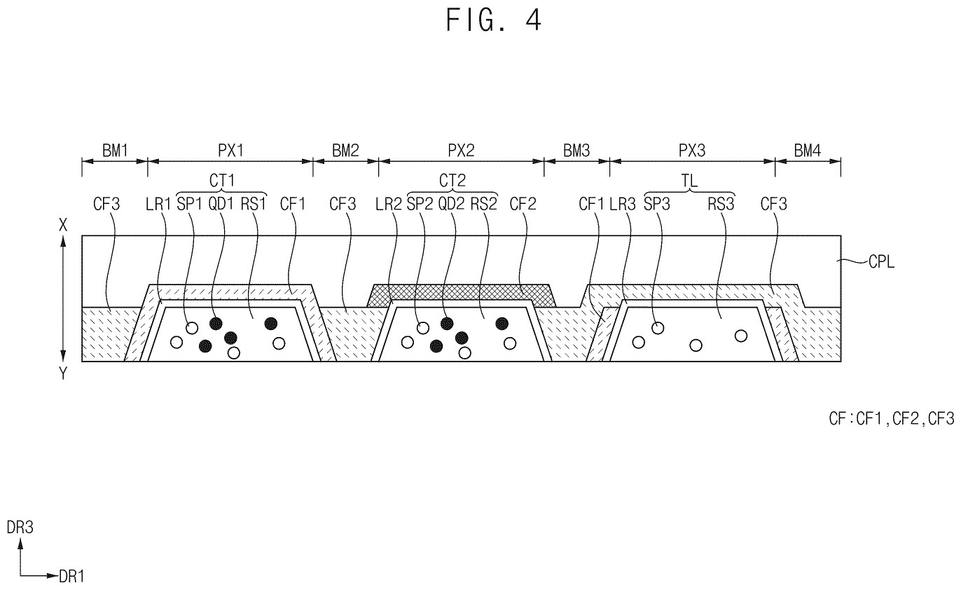

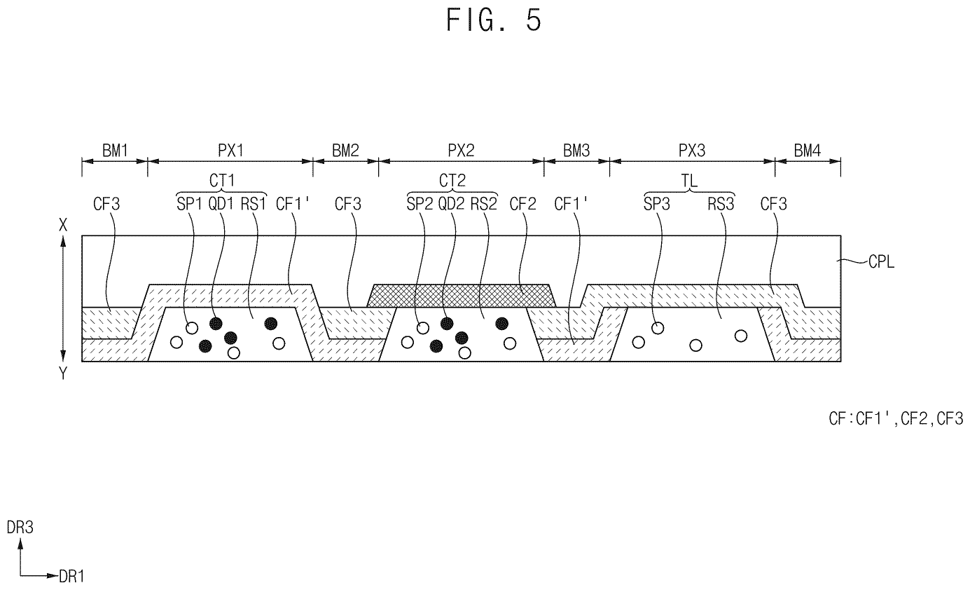

FIG. 3 is a cross-sectional view illustrating an example of an X-Y portion of FIG. 2. FIG. 4 is a cross-sectional view illustrating another example of an X-Y portion of FIG. 2. FIG. 5 is a cross-sectional view illustrating another example of an X-Y portion of FIG. 2.

Referring to FIGS. 2 and 3, the first color conversion layer CT1 may be disposed on the first light emitting element LED1. For example, the first color conversion layer CT1 may be disposed in the first pixel area PX1 on the encapsulation layer TFE. The first color conversion layer CT1 may include a first resin part RS1, a first scattering body SP1, and a first wavelength conversion particle QD1.

The first resin part RS1 may include an epoxy resin, an acrylic resin, a phenol resin, a melamine resin, a cardo resin, an imide resin, or the like. These materials may be used alone or in combination with each other.

The first scattering body SP1 may increase an optical path by scattering first incident light L1 without substantially converting a wavelength of the first incident light L1 incident on the first color conversion layer CT1. For example, the first scattering body SP1 may include a metal oxide, an organic material, or the like. These materials may be used alone or in combination with each other. For example, the first scattering body SP1 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

The first wavelength conversion particle QD1 may include a first quantum dot. The first quantum dot QD1 may absorb the first incident light L1 to emit light having a wavelength different from the wavelength of the first incident light L1. For example, the first wavelength conversion particle QD1 may absorb the first incident light L1 to emit red light. However, this disclosure is not limited thereto. For another example, the first wavelength conversion particle QD1 may absorb the first incident light L1 to emit green light.

For example, the first wavelength conversion particle QD1 may include a group II-VI compound, a group III-V compound, a group IV-VI compound, a group IV element, a group IV compound, or the like. These materials may be used alone or in combination with each other. For example, the group II-VI compound may include CdSe, CdTe, ZnS, ZnSe, ZnTe, ZnO, HgS, HgSe, or the like. The group III-V compound may include GaN, GaP, GaAs, GaSb, AlN, AlP, or the like. The group IV-VI compound may include SnS, SnSe, SnTe, PbS PbSe, or the like. The group IV element may include Si, Ge, or the like. The group IV compound may include SiC, SiGe, or the like.

The second color conversion layer CT2 may be disposed on the second light emitting element LED2. For example, the second color conversion layer CT2 may be disposed in the second pixel area PX2 on the encapsulation layer TFE. The second color conversion layer CT2 may include a second resin part RS2, a second scattering body SP2, and a second wavelength conversion particle QD2.

The second resin part RS2 may include an epoxy resin, an acrylic resin, a phenol resin, a melamine resin, a cardo resin, an imide resin, or the like. These materials may be used alone or in combination with each other.

In an embodiment, the first resin part RS1 and the second resin part RS2 may include substantially the same material. However, this disclosure is not limited thereto, and in another embodiment, the first resin part RS1 and the second resin part RS2 may include different materials.

The second scattering body SP2 may increase an optical path by scattering second incident light L2 without substantially converting a wavelength of the second incident light L2 incident on the second color conversion layer CT2. For example, the second scattering body SP2 may include a metal oxide, an organic material, or the like. These materials may be used alone or in combination with each other. For example, the second scattering body SP2 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

In an embodiment, the first scattering body SP1 and the second scattering body SP2 may include substantially the same material. However, this disclosure is not limited thereto, and in another embodiment, the first scattering body SP1 and the second scattering body SP2 may include different materials.

The second wavelength conversion particle QD2 may include a second quantum dot. The second quantum dot QD2 may absorb the second incident light L2 to emit light having a wavelength different from the wavelength of the second incident light L2. For example, the second wavelength conversion particle QD2 may absorb the second incident light L2 to emit green light. However, this disclosure is not limited thereto. For another example, the second wavelength conversion particle QD2 may absorb the second incident light L2 to emit red light.

For example, the second wavelength conversion particle QD2 may include a group II-VI compound, a group III-V compound, a group IV-VI compound, a group IV element, a group IV compound, or the like. These materials may be used alone or in combination with each other. For example, the group II-VI compound may include CdSe, CdTe, ZnS, ZnSe, ZnTe, ZnO, HgS, HgSe, or the like. The group III-V compound may include GaN, GaP, GaAs, GaSb, AlN, AlP, or the like. The group IV-VI compound may include SnS, SnSe, SnTe, PbS PbSe, or the like. The group IV element may include Si, Ge, or the like. The group IV compound may include SiC, SiGe, or the like.

The light transmitting layer TL may be disposed on the third light emitting element LED3. For example, the light transmitting layer TL may be disposed in the third pixel area PX3 on the encapsulation layer TFE. The light transmitting layer TL may include a third resin part RS3 and a third scattering body SP3. The light transmitting layer TL does not include a wavelength conversion particle such as quantum dot.

The third resin part RS3 may include an epoxy resin, an acrylic resin, a phenol resin, a melamine resin, a cardo resin, an imide resin, or the like. These materials may be used alone or in combination with each other.

In an embodiment, the first resin part RS1 and the third resin part RS3 may include substantially the same material. However, this disclosure is not limited thereto, and in another embodiment, the first resin part RS1 and the third resin part RS3 may include different materials.

The third scattering body SP3 may increase an optical path by scattering third incident light L3 without substantially converting a wavelength of the third incident light L3 incident on the third color conversion layer CT3. For example, the third scattering body SP3 may include a metal oxide, an organic material, or the like. These materials may be used alone or in combination with each other. For example, the third scattering body SP3 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

In an embodiment, the first scattering body SP1 and the third scattering body SP3 may include substantially the same material. However, this disclosure is not limited thereto, and in another embodiment, the first scattering body SP1 and the third scattering body SP3 may include different materials.

The color filter layer CF may include a first color filter layer CF1, a second color filter layer CF2, and a third color filter layer CF3.

The first color filter layer CF1 may cover the first color conversion layer CT1. For example, the first color filter layer CF1 may cover an upper surface CT1-U and a side surface CT1-S of the first color conversion layer CT1. That is, the first color filter layer CF1 may be disposed in the first pixel area PX1. In addition, the first color filter layer CF1 may be disposed in at least a portion of the first non-light emitting area BM1 and at least a portion of the second non-light emitting area BM2.

In an embodiment, the first color filter layer CF1 may cover a side surface TL-S of the light transmitting layer TL. That is, the first color filter layer CF1 may be disposed on at least a portion of the third non-light emitting area BM3 and at least a portion of the fourth non-light emitting area BM4.

For example, the first color filter layer CF1 may selectively transmit red light. However, this disclosure is not limited thereto. For another example, the first color filter layer CF1 may selectively transmit green light.

The second color filter layer CF2 may cover the second color conversion layer CT2. For example, the second color filter layer CF2 may cover an upper surface CT2-U of the second color conversion layer CT2. That is, the second color filter layer CF2 may be disposed in the second pixel area PX2.

In an embodiment, the second color filter layer CF2 may extend to at least a portion of the second non-light emitting area BM2. For example, the second color filter layer CF2 may cover at least a portion of an upper surface of the third color filter layer CF3 disposed in the second non-light emitting area BM2.

In an embodiment, the second color filter layer CF2 may extend to at least a portion of the third non-light emitting area BM3. For example, the second color filter layer CF2 may cover at least a portion of an upper surface of the third color filter layer CF3 disposed in the third non-light emitting area BM3.

For example, the second color filter layer CF2 may selectively transmit green light. However, this disclosure is not limited thereto. For another example, the second color filter layer CF2 may selectively transmit red light.

The third color filter layer CF3 may cover the light transmitting layer TL. For example, the third color filter layer CF3 may cover an upper surface TL-U of the light transmitting layer TL. That is, the third color filter layer CF3 may be disposed in the third pixel area PX3.

In an embodiment, the third color filter layer CF3 may cover the first color filter layer CF1 covering the light transmitting layer TL. For example, the third color filter layer CF3 may cover an upper surface and a side surface of the portion of the first color filter layer CF1 covering the light transmitting layer TL.

In an embodiment, the third color filter layer CF3 may be disposed in at least a portion of the first non-light emitting area BM1. In an embodiment, the third color filter layer CF3 may be disposed in at least a portion of the fourth non-light emitting area BM4.

In an embodiment, the third color filter layer CF3 may be disposed on at least a portion of the second non-light emitting area BM2. For example, the third color filter layer CF3 may be in contact with a side surface of the first color filter layer CF1. For example, the third color filter layer CF3 may be in contact with the side surface of the portion of the first color filter layer CF1 covering the first color conversion layer CT1.

In an embodiment, the third color filter layer CF3 may be disposed in at least a portion of the third non-light emitting area BM3. For example, the third color filter layer CF3 may be in contact with a side surface CT2-S of the second color conversion layer CT2. In an embodiment, the third color filter layer CF3 may selectively transmit blue light.

Portions of the first color filter layer CF1 and the third color filter layer CF3 may be disposed in the second non-light emitting area BM2. For example, the first color filter layer CF1 and the third color filter layer CF3 may be stacked in the first direction DR1 in the second non-light emitting area BM2. Accordingly, color mixing between the first pixel area PX1 and the second pixel area PX2 may be effectively prevented. In addition, a partial path of the first incident light L1 to the second pixel area PX2 may be blocked so that the first incident light L1 does not reach the second color conversion layer CT2, and a partial path of the second incident light L2 to the first pixel area PX1 may be blocked so that the second incident light L2 does not reach the first color conversion layer CT1.

The first color filter layer CF1 and the third color filter layer CF3 may be disposed in the third non-light emitting area BM3. For example, the first color filter layer CF1 and the third color filter layer CF3 may be stacked in the first direction DR1 in the third non-light emitting area BM3. Accordingly, color mixing between the second pixel area PX2 and the third pixel area PX3 may be effectively prevented. In addition, a partial path of the second incident light L2 to the third pixel area PX3 may be blocked so that the second incident light L2 does not reach the light transmitting layer TL, and a partial path of the third incident light L3 to the second pixel area PX2 may be blocked so that the third incident light L3 does not reach the second color conversion layer CT2.

The display device DD according to an embodiment may not include a bank layer. In general, the bank layer may define openings accommodating each of a first color conversion layer, a second color conversion layer, and a light transmitting layer. The bank layer may prevent color mixing between adjacent pixel areas. The display device DD according to an embodiment may include a color filter layer CF disposed between the first color conversion layer CT1 and the second color conversion layer CT2. For example, the display device DD may include a first color filter layer CF1 and a third color filter layer CF3 disposed between the first color conversion layer CT1 and the second color conversion layer CT2. Accordingly, color mixing between the first pixel area PX1 and the second pixel area PX2 may be effectively prevented even though the display device DD does not include the bank layer. In addition, the display device DD may include a color filter layer CF disposed between the second color conversion layer CT2 and the light transmitting layer TL. For example, the display device DD may include a first color filter layer CF1 and a third color filter layer CF3 disposed between the second color conversion layer CT2 and the light transmitting layer TL. Accordingly, color mixing between the second pixel area PX2 and the third pixel area PX3 may be prevented even though the display device DD does not include the bank layer. That is, color mixing between adjacent pixel areas may be effectively prevented even though the display device DD does not include the bank layer. In addition, since the display device DD does not include the bank layer, manufacturing cost and manufacturing time of the display device DD may be reduced.

In addition, since the bank layer is not disposed between adjacent pixel areas, the pixel area may have a sufficient size. For example, since the bank layer is not disposed between the first pixel area PX1 and the second pixel area PX2, the first pixel area PX1 and the second pixel area PX2 may have sufficient sizes. For example, since the bank layer is not disposed between the second pixel area PX2 and the third pixel area PX3, the second pixel area PX2 and the third pixel area PX3 may have sufficient sizes.

The capping layer CPL may be disposed on the color filter layer CF. For example, the capping layer CPL may cover the first color filter layer CF1, the second color filter layer CF2, and the third color filter layer CF3. In an embodiment, the capping layer CPL may include an inorganic material. Examples of the inorganic material that may be used as the capping layer CPL may include silicon oxide, silicon nitride, or the like. These materials may be used alone or in combination with each other.

In an embodiment, a width W1 of the second non-light emitting area BM2 in the first direction DR1 may be about 2 micrometers or more and about 4 micrometers or less. For example, the width W1 of the second non-light emitting area BM2 may be about 3 micrometers. That is, the first color conversion layer CT1 and the second color conversion layer CT2 may be spaced apart from each other by about 3 micrometers in the first direction DR1.

In an embodiment, a width W2 of the third non-light emitting area BM3 in the first direction DR1 may be about 2 micrometers or more and about 4 micrometers or less. For example, the width W2 of the third non-light emitting area BM3 may be about 3 micrometers. That is, the second color conversion layer CT2 and the light transmitting layer TL may be spaced apart from each other by about 3 micrometers in the first direction DR1.

In an embodiment, the width W2 of the third non-light emitting area BM3 and the width W1 of the second non-light emitting area BM2 may be substantially the same. However, this disclosure is not limited thereto, and in another embodiment, the width W2 of the third non-light emitting area BM3 and the width W1 of the second non-light emitting area BM2 may be different from each other. For example, the width W2 of the third non-light emitting area BM3 may be greater than the width W1 of the second non-light emitting area BM2.

Referring to FIGS. 2 and 4, the display device DD may further include a first low refractive index layer LR1, a second low refractive index layer LR2, and a third low refractive index layer LR3.

For example, the first low refractive index layer LR1 may be disposed between the first color conversion layer CT1 and the first color filter layer CF1. For example, the first low refractive index layer LR1 may cover the first color conversion layer CT1, and the first color filter layer CF1 may cover the first low refractive index layer LR1. The first low refractive index layer LR1 may be disposed in the first pixel area PX1.

For example, the second low refractive index layer LR2 may be disposed between the second color conversion layer CT2 and the second color filter layer CF2. For example, the second low refractive index layer LR2 may cover the second color conversion layer CT2, and the second color filter layer CF2 may cover the second low refractive index layer LR2. In addition, the third color filter layer CF3 may cover at least a portion of the second low refractive index layer LR2. For example, the third color filter layer CF3 may cover a side surface of the second low refractive index layer LR2.

For example, the third low refractive index layer LR3 may be disposed between the light transmitting layer TL and the third color filter layer CF3. For example, the third low refractive index layer LR3 may cover the light transmitting layer TL, and the third color filter layer CF3 may cover the third low refractive index layer LR3. In addition, the first color filter layer CF1 may cover at least a portion of the third low refractive index layer LR3. For example, the first color filter layer CF1 may cover a side surface of the third low refractive index layer LR3.

Each of the first low refractive index layer LR1, the second low refractive index layer LR2, and the third low refractive index layer LR3 may improve light extraction efficiency, thereby increasing brightness and lifespan of the display device DD. For example, the first low refractive index layer LR1 may improve light extraction efficiency of the first incident light L1, the second low refractive index layer LR2 may improve light extraction efficiency of the second incident light L2, and the third low refractive index layer LR3 may improve light extraction efficiency of the third incident light L3.

For example, each of the first low refractive index layer LR1, the second low refractive index layer LR2, and the third low refractive index layer LR3 may include an organic material. For example, each of the first low refractive index layer LR1, the second low refractive index layer LR2, and the third low refractive index layer LR3 may include an organic polymer material including silicon.

Referring to FIGS. 2 and 5, in still another embodiment, a first color filter layer CF1′ may be disposed in an entirety of the first non-light emitting area BM1. In addition, the first color filter layer CF1′ may be disposed in an entirety of the second non-light emitting area BM2. In addition, the first color filter layer CF1′ may be disposed in an entirety of the third non-light emitting area BM3. For example, the first color filter layer CF1′ may be in contact with the side surface of the second color conversion layer CT2. In addition, the first color filter layer CF1′ may be disposed in an entirety of the fourth non-light emitting area BM4.

A color filter layer CF′ may include the first color filter layer CF1′, a second color filter layer CF2, and a third color filter layer CF3.

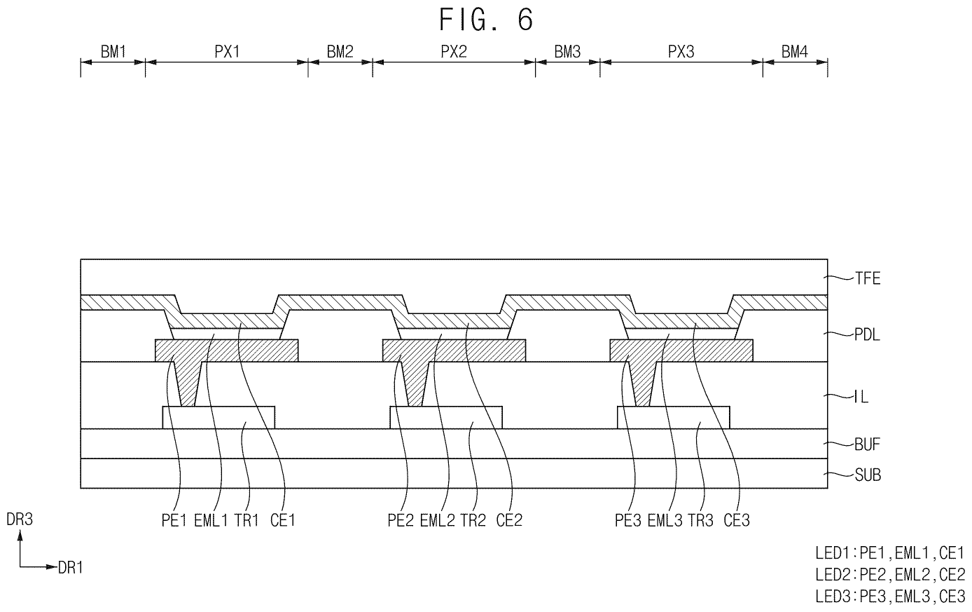

FIGS. 6, 7, 8, 9, 10, 11, 12, 13, and 14 are cross-sectional views illustrating a method of manufacturing the display device of FIG. 2.

Referring to FIG. 6, the buffer layer BUF may be formed on the substrate SUB. For example,

[symbol]

The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like.

Alternatively, the substrate SUB may include a quartz substrate (e.g., a synthetic quartz substrate, a fluorine-doped quartz substrate), a calcium fluoride substrate, a sodalime glass substrate, a non-alkali glass substrate, or the like. These materials may be used alone or in combination with each other.

For example, the buffer layer BUF may include an inorganic material such as silicon oxide, silicon nitride, silicon oxynitride, or the like. These materials may be used alone or in combination with each other.

The first transistor TR1, the second transistor TR2, and the third transistor TR3 may be formed on the buffer layer BUF. The first transistor TR1 may be formed in at least a portion of the first pixel area PX1. The second transistor TR2 may be formed in at least a portion of the second pixel area PX2. The third transistor TR3 may be formed in at least a portion of the third pixel area PX3.

For example, each of the first transistor TR1, the second transistor TR2, and the third transistor TR3 may include polycrystalline silicon or a metal oxide semiconductor.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The insulating layer IL may be formed on the buffer layer BUF. The insulating layer IL may be formed to cover the first transistor TR1, the second transistor TR2, and the third transistor TR3. For example, the insulating layer IL may include at least one inorganic insulating layer and at least one organic insulating layer.

For example, the inorganic insulating layer may include silicon oxide, silicon nitride, silicon carbide, silicon oxynitride, silicon oxycarbide, or the like. These materials may be used alone or in combination with each other.

In addition, the organic insulating layer may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The first pixel electrode PE1, the second pixel electrode PE2, and the third pixel electrode PE3 may be formed on the insulating layer IL. The first pixel electrode PE1 may be formed in the first pixel area PX1. The second pixel electrode PE2 may be formed in the second pixel area PX2. The third pixel electrode PE3 may be formed in the third pixel area PX3.

A first contact hole may be formed by removing a portion of the insulating layer IL. The first pixel electrode PE1 may be connected to the first transistor TR1 through the first contact hole. A second contact hole may be formed by removing a portion of the insulating layer IL. The second pixel electrode PE2 may be connected to the second transistor TR2 through the second contact hole. A third contact hole may be formed by removing a portion of the insulating layer IL. The third pixel electrode PE3 may be connected to the third transistor TR3 through the third contact hole.

For example, each of the first pixel electrode PE1, the second pixel electrode PE2, and the third pixel electrode PE3 may include a metal, an alloy, a metal nitride, a conductive metal oxide, a transparent conductive material, or the like. These materials may be used alone or in combination with each other.

The pixel defining layer PDL may be formed on the insulating layer IL, the first pixel electrode PE1, the second pixel electrode PE2, and the third pixel electrode PE3. For example, the pixel defining layer PDL may be formed in the first non-light emitting area BM1, the second non-light emitting area BM2, the third non-light emitting area BM3, and the fourth non-light emitting area BM4.

The pixel defining layer PDL may be formed to cover a side portion of each of the first pixel electrode PE1, the second pixel electrode PE2, and the third pixel electrode PE3. In addition, the pixel defining layer PDL may be formed to expose an upper surface of each of the first pixel electrode PE1, the second pixel electrode PE2, and the third pixel electrode PE3.

For example, the pixel defining layer PDL may include an organic material and/or an inorganic material. In an embodiment, the pixel defining layer PDL may include an organic material. For example, the pixel defining layer PDL may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The first light emitting layer EML1 may be formed on the first pixel electrode PE1. For example, the first light emitting layer EML1 may be formed in the first pixel area PX1. The second light emitting layer EML2 may be formed on the second pixel electrode PE2. For example, the second light emitting layer EML2 may be formed in the second pixel area PX2. The third light emitting layer EML3 may be disposed on the third pixel electrode PE3. For example, the third light emitting layer EML3 may be formed in the third pixel area PX3.

The first common electrode CE1 may be formed on the first light emitting layer EML1. For example, the first common electrode CE1 may be formed in the first pixel area PX1. The second common electrode CE2 may be formed on the second light emitting layer EML2. For example, the second common electrode CE2 may be formed in the second pixel area PX2. The third common electrode CE3 may be formed on the third light emitting layer EML3. For example, the third common electrode CE3 may be formed in the third pixel area PX3.

In an embodiment, the first common electrode CE1, the second common electrode CE2, and the third common electrode CE3 may be integrally formed. However, this disclosure is not limited thereto, and in another embodiment, the first common electrode CE1 may be formed separately from the second common electrode CE2, and the second common electrode CE2 may be formed separately from the third common electrode CE3.

For example, each of the first common electrode CE1, the second common electrode CE2, and the third common electrode CE3 may include a metal, an alloy, a metal nitride, a conductive metal oxide, a transparent conductive material, or the like. These materials may be used alone or in combination with each other.

The encapsulation layer TFE may be formed on the first common electrode CE1, the second common electrode CE2, and the third common electrode CE3. For example, the encapsulation layer TFE may include at least one inorganic encapsulation layer and at least one organic encapsulation layer. For example, the inorganic encapsulation layer may include silicon oxide, silicon nitride, silicon oxynitride, or the like. These materials may be used alone or in combination with each other. The organic encapsulation layer may include a polymer cured product such as polyacrylate.

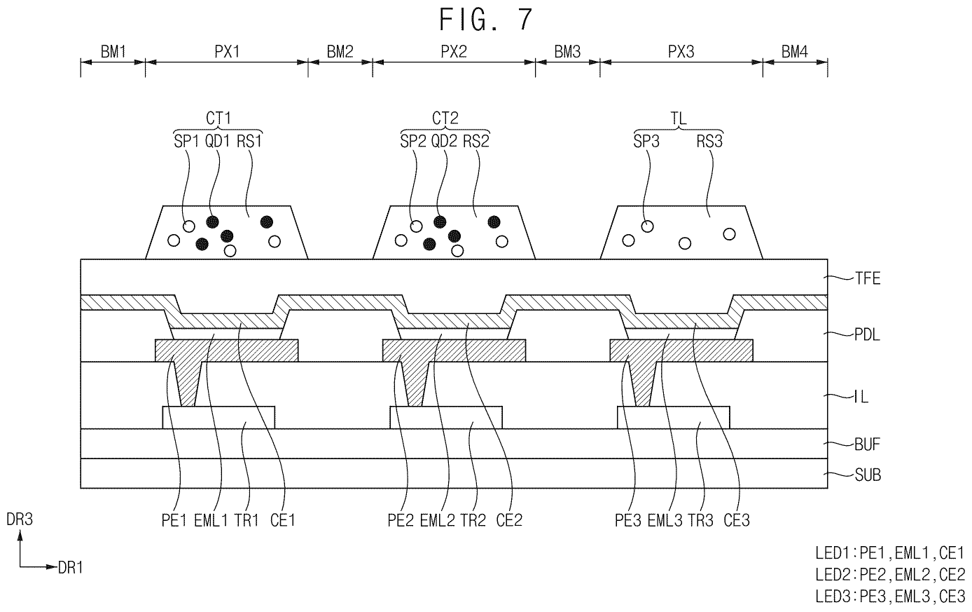

Referring to FIG. 7, the first color conversion layer CT1 may be formed on the encapsulation layer TFE. The first color conversion layer CT1 may be formed in the first pixel area PX1. For example, a first preliminary color conversion layer may be formed on the encapsulation layer TFE, a first photoresist layer may be formed on the first preliminary color conversion layer, and a first mask may be formed on the first photoresist layer.

The first mask may include a transmitting area and a light blocking area. In the transmitting area, light may pass through the first mask to the first photoresist layer. Light may not pass through the first mask to the first photoresist layer in the light blocking area.

For example, the first photoresist layer may be a negative photoresist or a positive photoresist. In the following specification, for convenience of description, all photoresist layers will be described based on the case of a negative photoresist.

A portion of the first photoresist layer overlapping the light blocking area may be dissolved after an exposure process and a development process. A portion of the first photoresist layer overlapping the transmitting area may not be dissolved even after an exposure process and a development process.

The transmitting area of the first mask may overlap a first pixel area PX1 in a plan view. The light blocking area of the first mask may overlap the first non-light emitting area BM1, the second non-light emitting area BM2, the third non-light emitting area BM3, the third pixel area PX3, and the fourth non-light emitting area BM4 in a plan view.

The first photoresist layer may undergo an exposure process and a development process using the first mask. Accordingly, a first photoresist pattern may be formed. The first preliminary color conversion layer may be etched using the first photoresist pattern. Accordingly, the first color conversion layer CT1 may be formed.

The first color conversion layer CT1 may include the first resin part RS1, the first scattering body SP1, and the first wavelength conversion particle QD1.

For example, the first resin part RS1 may include an epoxy resin, an acrylic resin, a phenol resin, a melamine resin, a cardo resin, an imide resin, or the like. These materials may be used alone or in combination with each other.

For example, the first scattering body SP1 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

For example, the first wavelength conversion particle QD1 may include a group II-VI compound, a group III-V compound, a group IV-VI compound, a group IV element, a group IV compound, or the like. These materials may be used alone or in combination with each other. For example, the group II-VI compound may include CdSe, CdTe, ZnS, ZnSe, ZnTe, ZnO, HgS, HgSe, or the like. The group III-V compound may include GaN, GaP, GaAs, GaSb, AlN, AlP, or the like. The group IV-VI compound may include SnS, SnSe, SnTe, PbS PbSe, or the like. The group IV element may include Si, Ge, or the like. The group IV compound may include SiC, SiGe, or the like.

The second color conversion layer CT2 may be formed on the encapsulation layer TFE. The second color conversion layer CT2 may be formed in the second pixel area PX2. For example, a second preliminary color conversion layer may be formed on the encapsulation layer TFE, a second photoresist layer may be formed on the second preliminary color conversion layer, and a second mask may be formed on the second photoresist layer. The second mask may include a transmitting area and a light blocking area.

The transmitting area of the second mask may overlap a second pixel area PX2 in a plan view. The light blocking area of the second mask may overlap the first non-light emitting area BM1, the first pixel area PX1, the second non-light emitting area BM2, the third non-light emitting area BM3, the third pixel area PX3, and the fourth non-light emitting area BM4 in a plan view.

The second photoresist layer may undergo an exposure process and a development process using the second mask. Accordingly, a second photoresist pattern may be formed. The second preliminary color conversion layer may be etched using the second photoresist pattern. Accordingly, the second color conversion layer CT2 may be formed.

The second color conversion layer CT2 may include the second resin part RS2, the second scattering body SP2, and the second wavelength conversion particle QD2.

For example, the second resin part RS2 may include an epoxy resin, an acrylic resin, a phenol resin, a melamine resin, a cardo resin, an imide resin, or the like. These materials may be used alone or in combination with each other.

For example, the second scattering body SP2 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

For example, the second wavelength conversion particle QD2 may include a group II-VI compound, a group III-V compound, a group IV-VI compound, a group IV element, a group IV compound, or the like. These materials may be used alone or in combination with each other. For example, the group II-VI compound may include CdSe, CdTe, ZnS, ZnSe, ZnTe, ZnO, HgS, HgSe, or the like. The group III-V compound may include GaN, GaP, GaAs, GaSb, AlN, AlP, or the like. The group IV-VI compound may include SnS, SnSe, SnTe, PbS PbSe, or the like. The group IV element may include Si, Ge, or the like. The group IV compound may include SiC, SiGe, or the like.

The light transmitting layer TL may be formed on the encapsulation layer TFE. The light transmitting layer TL may be formed in the third pixel area PX3. For example, a preliminary light transmitting layer may be formed on the encapsulation layer TFE, a third photoresist layer may be formed on the preliminary light transmitting layer, and a third mask may be formed on the third photoresist layer. The third mask may include a transmitting area and a light blocking area.

The transmitting area of the third mask may overlap the third pixel area PX3 in a plan view. The light blocking area of the third mask may overlap the first non-light emitting area BM1, the first pixel area PX1, the second non-light emitting area BM2, the third non-light emitting area BM3 and the fourth non-light emitting area BM4 in a plan view.

The third photoresist layer may undergo an exposure process and a development process using the third mask. Accordingly, a third photoresist pattern may be formed. The preliminary light transmitting layer may be etched using the third photoresist pattern. Accordingly, the light transmitting layer TL may be formed.

For example, the light transmitting layer TL may include the third resin part RS3 and the third scattering body SP3.

For example, the third resin part RS3 may include an epoxy resin, an acrylic resin, a phenol resin, a melamine resin, a cardo resin, an imide resin, or the like. These materials may be used alone or in combination with each other.

For example, the third scattering body SP3 may include titanium dioxide (“TiO₂”), silicon dioxide (“SiO₂”), barium sulfate (“BaSO₄”), zinc oxide (“ZnO”), aluminum oxide (“Al₂O₃”), calcium carbonate (“CaCO₃”), or the like. These materials may be used alone or in combination with each other.

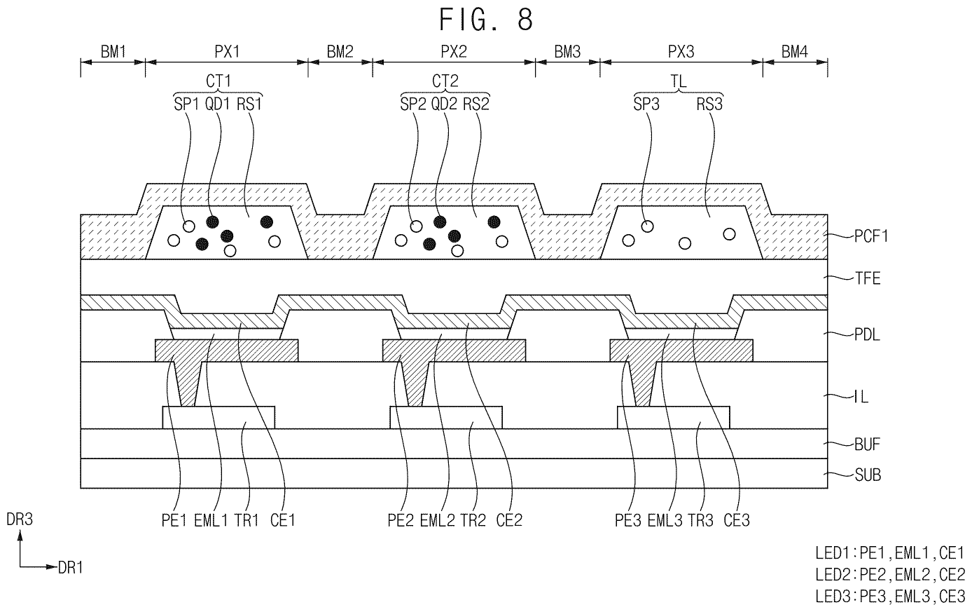

Referring to FIG. 8, a first preliminary color filter layer PCF1 may be formed on the first color conversion layer CT1, the second color conversion layer CT2, the light transmitting layer TL, and the encapsulation layer TFE. For example, the first preliminary color filter layer PCF1 may be formed to cover the first color conversion layer CT1, the second color conversion layer CT2, the light transmitting layer TL, and the encapsulation layer TFE.

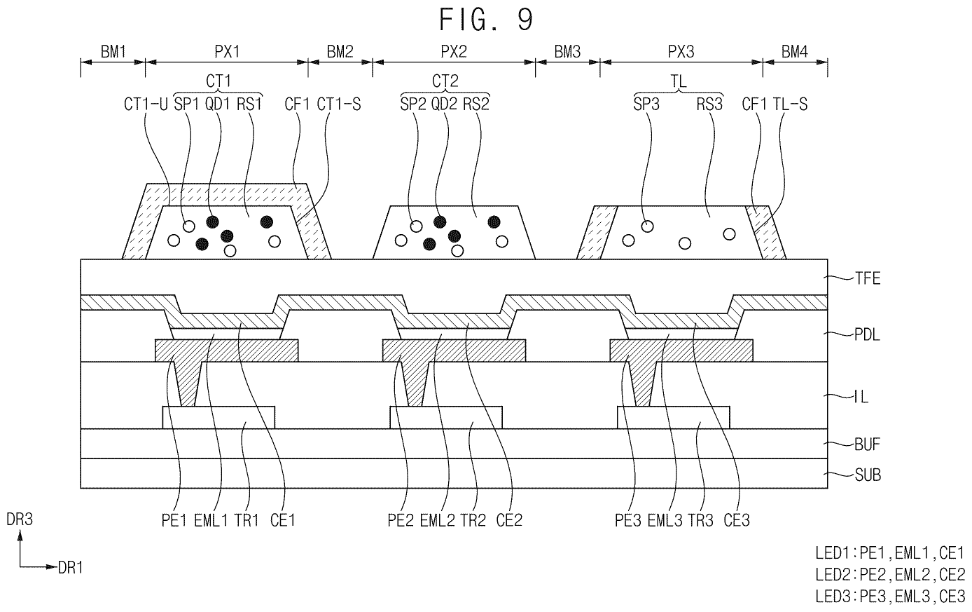

Referring to FIGS. 8 and 9, the first color filter layer CF1 may be formed by removing a portion of the first preliminary color filter layer PCF1. For example, the first color filter layer CF1 may be formed to cover the first color conversion layer CT1. For example, the first color filter layer CF1 may be formed to cover the upper surface CT1-U and the side surface CT1-S of the first color conversion layer CT1. In addition, the first color filter layer CF1 may be formed to cover the side surface TL-S of the light transmitting layer TL.

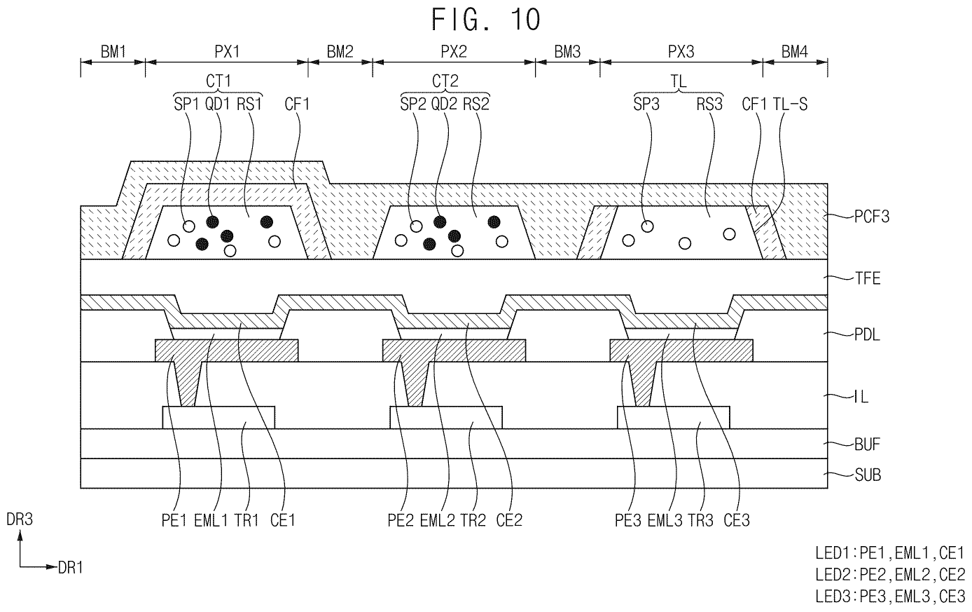

Referring to FIG. 10, a third preliminary color filter layer PCF3 may be formed on the first color conversion layer CT1, the second color conversion layer CT2, the light transmitting layer TL, and the encapsulation layer TFE. For example, the third preliminary color filter layer PCF3 may be formed to cover the first color conversion layer CT1, the second color conversion layer CT2, the light transmitting layer TL, and the encapsulation layer TFE. For example, the third preliminary color filter layer PCF3 may be formed to cover the first color filter layer CF1 covering the first color conversion layer CT1, the second color conversion layer CT2, the light transmitting layer TL, the first color filter layer CF1 covering the side surface TL-S of the light transmitting layer TL, and the encapsulation layer TFE.

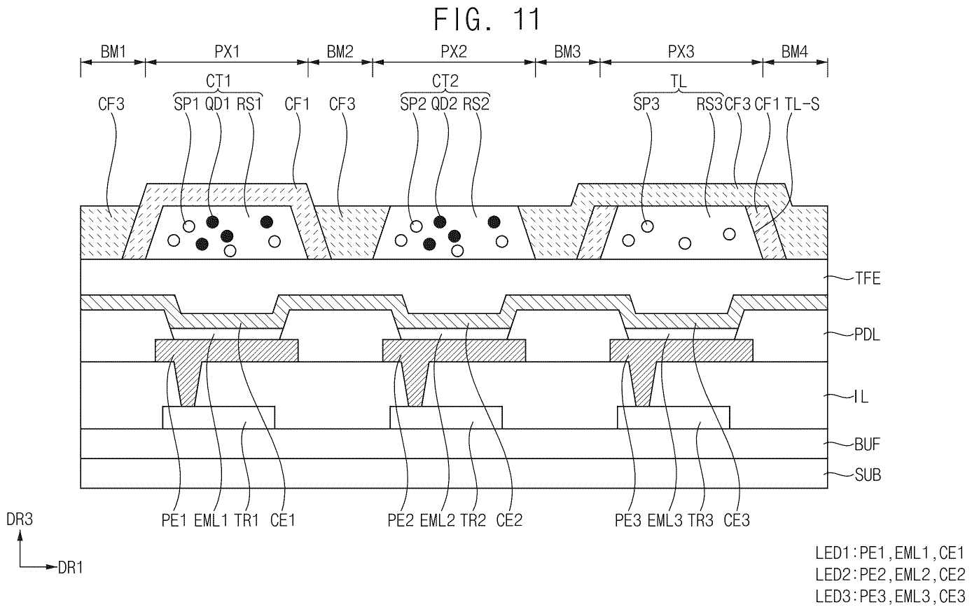

Referring to FIGS. 10 and 11, the third color filter layer CF3 may be formed by removing a portion of the third preliminary color filter layer PCF3. For example, the third color filter layer CF3 may cover the light transmitting layer TL, and may be formed to be disposed in the third non-light emitting area BM3 and the fourth non-light emitting area BM4. For example, the third color filter layer CF3 may be formed to cover the upper surface and the side surface of the portion of the first color filter layer CF1 covering the side surface TL-S of the light transmitting layer TL.

In addition, the third color filter layer CF3 may be formed to be disposed in the first non-light emitting area BM1 and the second non-light emitting area BM2. For example, the third color filter layer CF3 may be formed to cover the side surface of the portion of the first color filter layer CF1 covering the first color conversion layer CT1.

For example, a portion of the third preliminary color filter layer PCF3 may be removed using a photoresist layer and a mask, as in a method of forming the first color conversion layer CT1, the second color conversion layer CT2, and the light transmitting layer TL. Accordingly, the third color filter layer CF3 may be formed.

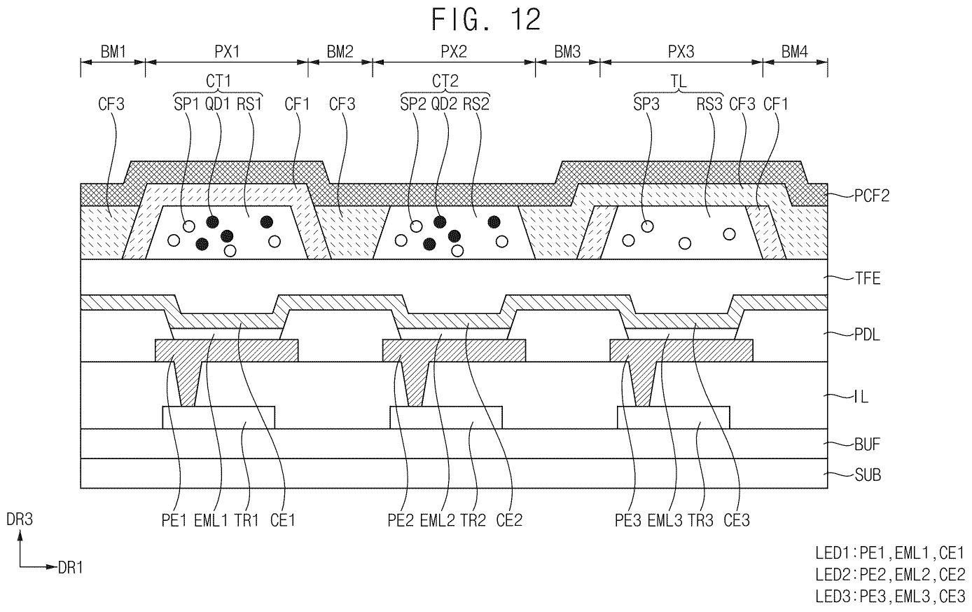

Referring to FIG. 12, the second preliminary color filter layer PCF2 may be formed on the first color conversion layer CT1, the second color conversion layer CT2, and the light transmitting layer TL. For example, the second preliminary color filter layer PCF2 may be formed to cover the first color conversion layer CT1, the second color conversion layer CT2, and the light transmitting layer TL. For example, the second preliminary color filter layer PCF2 may be formed to cover the third color filter layer CF3, the first color filter layer CF1 covering the first color conversion layer CT1, and the second color conversion layer CT2.

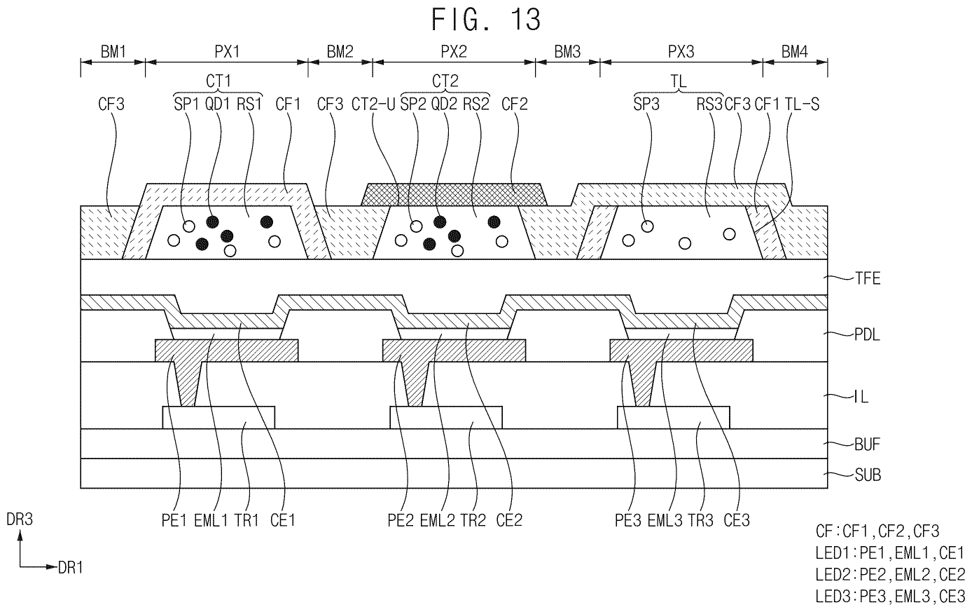

Referring to FIGS. 12 and 13, the second color filter layer CF2 may be formed by removing a portion of the second preliminary color filter layer PCF2. For example, the second color filter layer CF2 may be formed to cover the upper surface CT2-U of the second color conversion layer CT2. In addition, the second color filter layer CF2 may be formed to extend to a portion of the upper surface of the portion of the third color filter layer CF3 covering the side surface TL-S of the light transmitting layer TL.

For example, a portion of the third preliminary color filter layer PCF3 may be removed by using a photoresist layer and a mask, as in a method of forming the first color conversion layer CT1, the second color conversion layer CT2, and the light transmitting layer TL. Accordingly, the third color filter layer CF3 may be formed.

In an embodiment, the forming the third color filter layer CF3 may be performed before the forming the second color filter layer CF2.

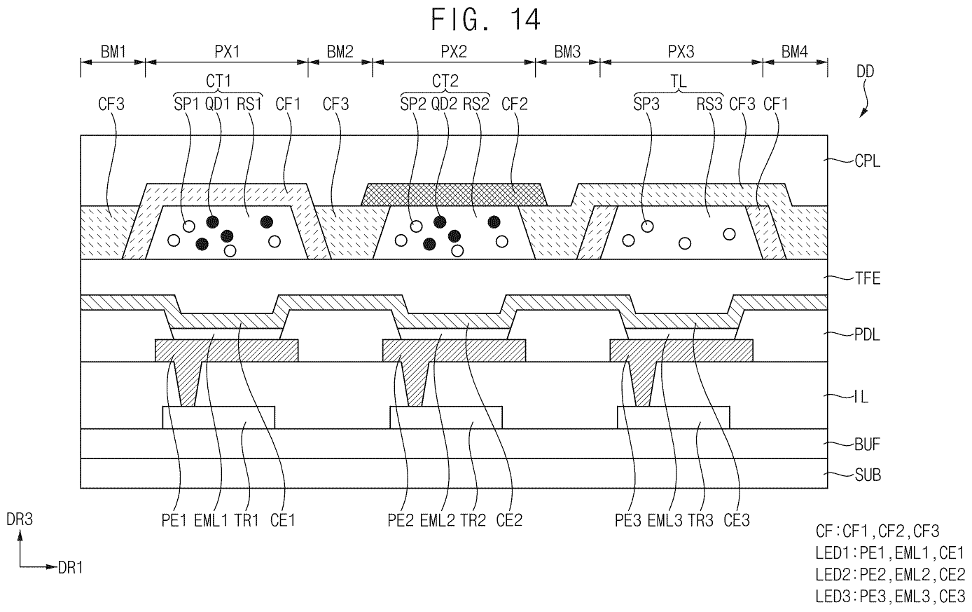

Referring to FIG. 14, the capping layer CPL may be formed on the color filter layer CF. For example, the capping layer CPL may be formed to cover the first color filter layer CF1, the second color filter layer CF2, and the third color filter layer CF3.

For example, the capping layer CPL may include an inorganic material. Examples of the inorganic material that can be used as the capping layer CPL may include silicon oxide, silicon nitride, or the like. These materials may be used alone or in combination with each other.

A method of manufacturing the display device DD according to an embodiment may not include a process of manufacturing each of a display unit and a color filter unit and bonding the display unit and the color filter unit. Accordingly, a manufacturing process of the display device DD may be simplified, and thus manufacturing cost and manufacturing time of the display device DD may be reduced. The display unit may include a light emitting element, and the color filter unit may include a color conversion layer and a color filter layer.

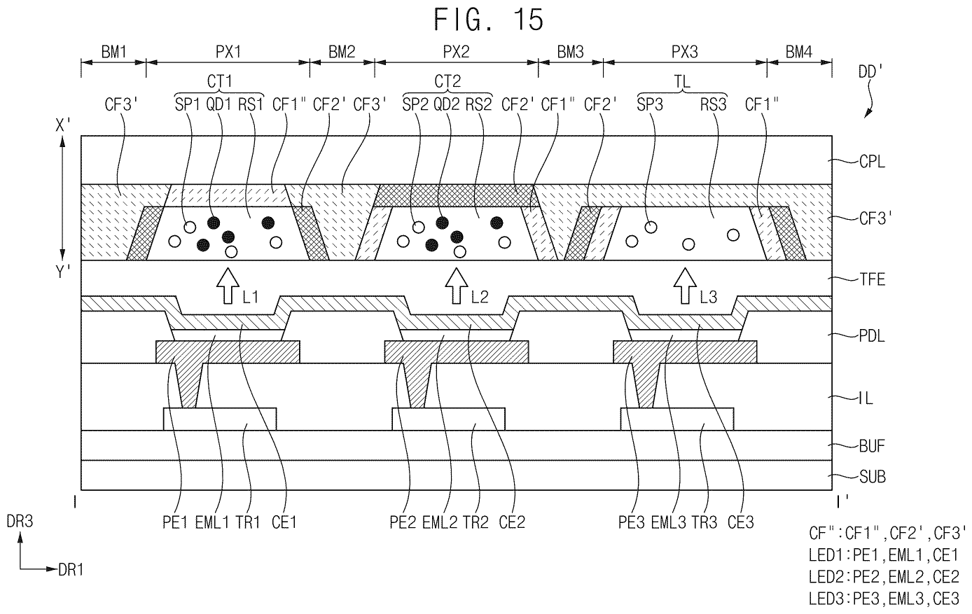

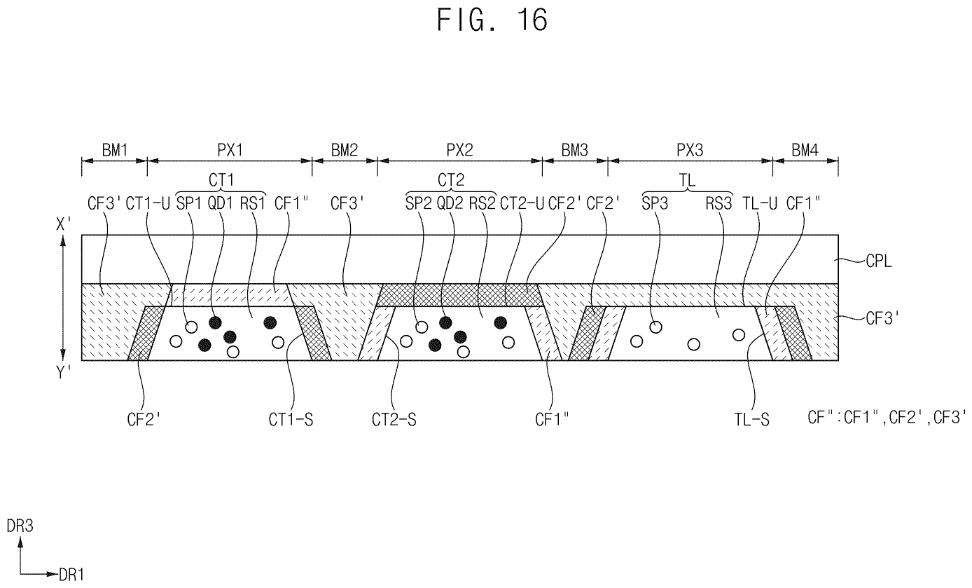

FIG. 15 is a cross-sectional view illustrating a display device according to another embodiment. Specifically, FIG. 15 is a cross-sectional view of a display device according to another embodiment taken along line I-I′ of FIG. 1. FIG. 16 is a cross-sectional view illustrating an X′-Y′ portion of FIG. 15.

In describing a display device DD′ of FIG. 15, substantially the same elements as the display device DD of FIG. 2 are denoted by the same reference numerals, and a detailed description thereof may be omitted. The display device DD′ of FIG. 15 may be substantially the same as or similar to the display device DD of FIG. 2, except for configuration of the color filter layer CF″.

Referring to FIGS. 15 and 16, a display device DD′ according to another embodiment may include the substrate SUB, the buffer layer BUF, the insulating layer IL, the first transistor TR1, the second transistor TR2, the third transistor TR3, the first light emitting element LED1, the second light emitting element LED2, the third light emitting element LED3, the pixel defining layer PDL, the encapsulation layer TFE, a color filter layer CF″, the first color conversion layer CT1, the second color conversion layer CT2, the light transmitting layer TL, and the capping layer CPL.

The color filter layer CF″ may include a first color filter layer CF1″, a second color filter layer CF′, and a third color filter layer CF3′.

The first color filter layer CF1″ may cover the first color conversion layer CT1. For example, the first color filter layer CF1″ may cover the upper surface CT1-U of the first color conversion layer CT1. In addition, the first color filter layer CF1″ may cover the second color conversion layer CT2. For example, the first color filter layer CF1″ may cover the side surface CT2-S of the second color conversion layer CT2. In addition, the first color filter layer CF1″ may cover the light transmitting layer TL. For example, the first color filter layer CF1″ may cover the side surface TL-S of the light transmitting layer TL.

For example, the first color filter layer CF1″ may selectively transmit red light. However, this disclosure is not limited thereto. For another example, the first color filter layer CF1″ may selectively transmit green light.

The second color filter layer CF2′ may cover the second color conversion layer CT2. For example, the second color filter layer CF2′ may cover the upper surface CT2-U of the second color conversion layer CT2. In addition, the second color filter layer CF2′ may cover the upper surface of the portion of the first color filter layer CF1″ covering the side surface CT2-S of the second color conversion layer CT2.

In addition, the second color filter layer CF2′ may cover the first color conversion layer CT1. For example, the second color filter layer CF2′ may cover the side surface CT1-S of the first color conversion layer CT1.

In addition, the second color filter layer CF2′ may cover the side surface TL-S of the light transmitting layer TL. For example, the second color filter layer CF2′ may cover the side surface of the portion of the first color filter layer CF1″ covering the side surface TL-S of the light transmitting layer TL.

For example, the second color filter layer CF2′ may selectively transmit green light. However, this disclosure is not limited thereto. For another example, the second color filter layer CF2′ may selectively transmit red light.

The third color filter layer CF3′ may cover the light transmitting layer TL. For example, the third color filter layer CF3′ may cover the upper surface TL-U of the light transmitting layer TL. In addition, the third color filter layer CF3′ may cover the upper surface of the portion of the first color filter layer CF1″ covering the side surface TL-S of the light transmitting layer TL. In addition, the third color filter layer CF3′ may cover the upper surface of the portion of the second color filter layer CF2′ covering the side surface of the first color filter layer CF1″.

The third color filter layer CF3′ may be disposed on at least a portion of the first non-light emitting area BM1. For example, the third color filter layer CF3′ may be disposed in an entirety of the first non-light emitting area BM1. The third color filter layer CF3′ may be disposed in at least a portion of the fourth non-light emitting area BM4. For example, the third color filter layer CF3′ may be disposed in an entirety of the fourth non-light emitting area BM4.

The third color filter layer CF3′ may be disposed in at least a portion of the second non-light emitting area BM2. For example, the third color filter layer CF3′ may be disposed in an entirety of the second non-light emitting area BM2. For example, the third color filter layer CF3′ may cover the second color filter layer CF2′ covering the side surface CT1-S of the first color conversion layer CT1. In addition, the third color filter layer CF3′ may cover the side surface of the first color filter layer CF1″ covering the upper surface CT1-U of the first color conversion layer CT1.

The third color filter layer CF3′ may be disposed in at least a portion of the third non-light emitting area BM3. For example, the third color filter layer CF3′ may be disposed in an entirety of the third non-light emitting area BM3. For example, the third color filter layer CF3′ may cover the side surface of the portion of the first color filter layer CF1″ covering the side surface CT2-S of the second color conversion layer CT2. In addition, the third color filter layer CF3′ may cover the side surface of the portion of the second color filter layer CF2′ covering the upper surface CT2-U of the second color conversion layer CT2.

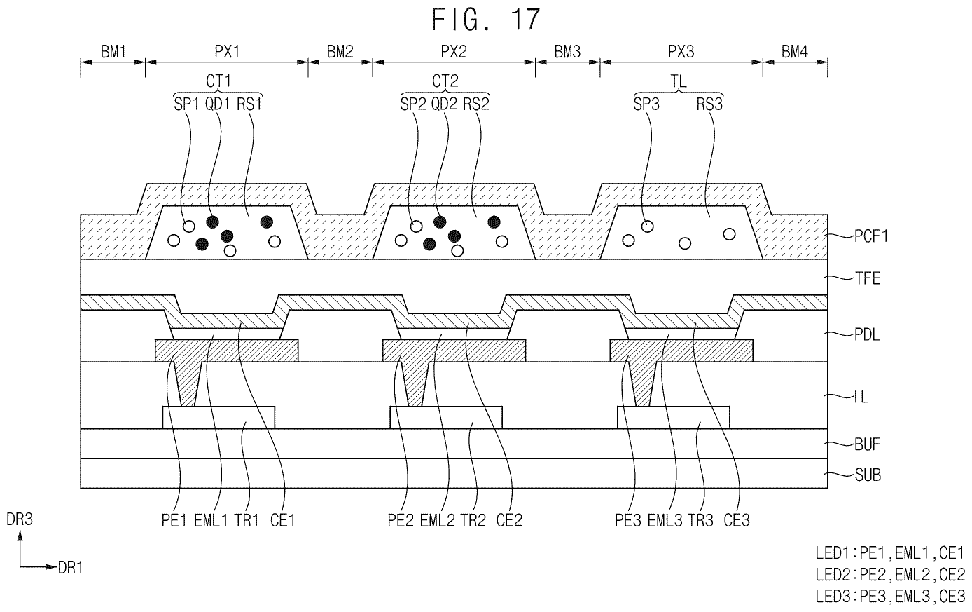

FIGS. 17, 18, 19, 20, 21, 22 and 23 are cross-sectional views illustrating a method of manufacturing the display device of FIG. 15.

A method of manufacturing the display device DD′ according to another embodiment of FIGS. 17, 18, 19, 20, 21, 22, and 23 may be substantially the same as or similar to the method of manufacturing the display device DD described with reference to FIGS. 6, 7, 8, 9, 10, 11, 12, 13, and 14 except for forming the color filter layer CF″. Therefore, repeated descriptions may be omitted.

Referring to FIG. 17, the first preliminary color filter layer PCF1 may be formed on the first color conversion layer CT1, the second color conversion layer CT2, the light transmitting layer TL, and the encapsulation layer TFE. For example, the first preliminary color filter layer PCF1 may be formed to cover the first color conversion layer CT1, the second color conversion layer CT2, the light transmitting layer TL, and the encapsulation layer TFE.

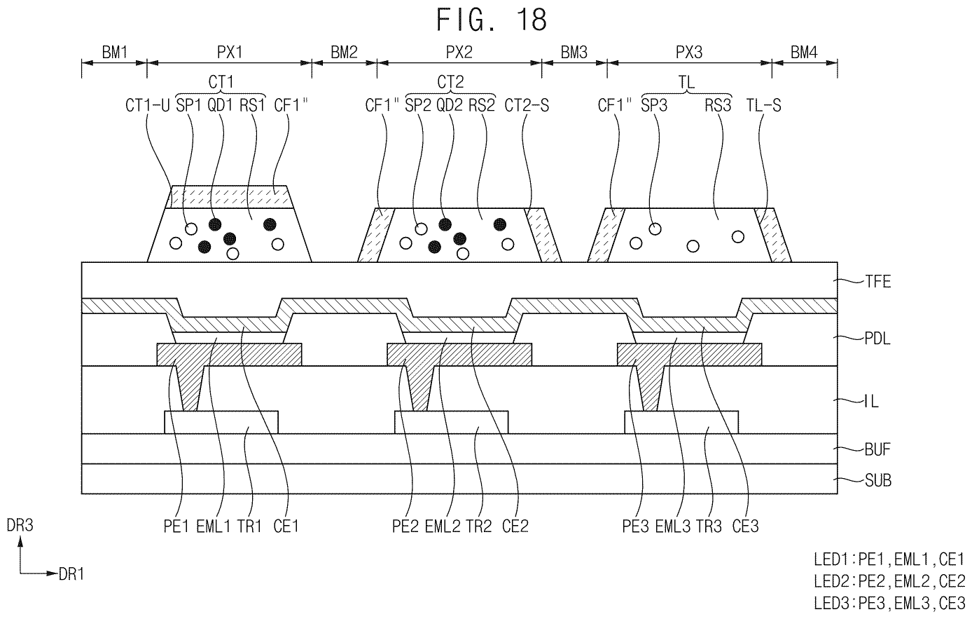

Referring to FIGS. 17 and 18, a first color filter layer CF1″ may be formed by removing a portion of the first preliminary color filter layer PCF1. For example, the first color filter layer CF1″ may be formed to cover the first color conversion layer CT1. For example, the first color filter layer CF1″ may be formed to cover the upper surface CT1-U of the first color conversion layer CT1.

In addition, the first color filter layer CF1″ may be formed to cover the second color conversion layer CT2. For example, the first color filter layer CF1″ may be formed to cover the side surface CT2-S of the second color conversion layer CT2. In addition, the first color filter layer CF1″ may be formed to cover the light transmitting layer TL. For example, the first color filter layer CF1″ may be formed to cover the side surface TL-S of the light transmitting layer TL. In addition, the first color filter layer CF1″ may be formed to cover the second color conversion layer CT2. For example, the first color filter layer CF1″ may be formed to cover the side surface CT2-S of the second color conversion layer CT2. In addition, the first color filter layer CF1″ may be formed to cover the light transmitting layer TL. For example, the first color filter layer CF1″ may be formed to cover the side surface TL-S of the light transmitting layer TL.

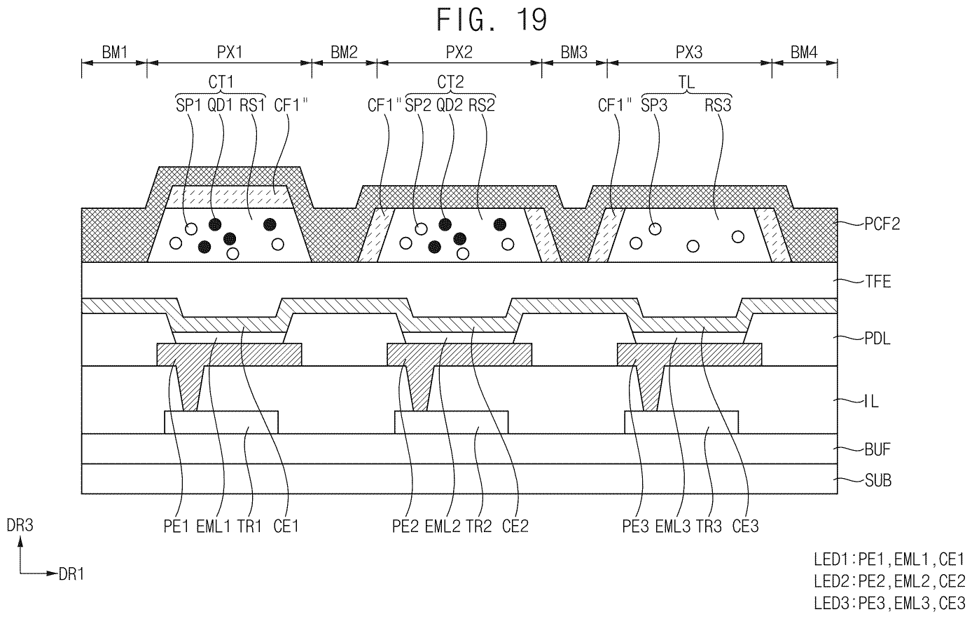

Referring to FIG. 19, the second preliminary color filter layer PCF2 may be formed on the first color conversion layer CT1, the second color conversion layer CT2, the light transmitting layer TL, and the encapsulation layer TFE. For example, the second preliminary color filter layer PCF2 may be formed to cover the first color conversion layer CT1, the second color conversion layer CT2, the light transmitting layer TL, the encapsulation layer TFE, and the first color filter layer CF1″.

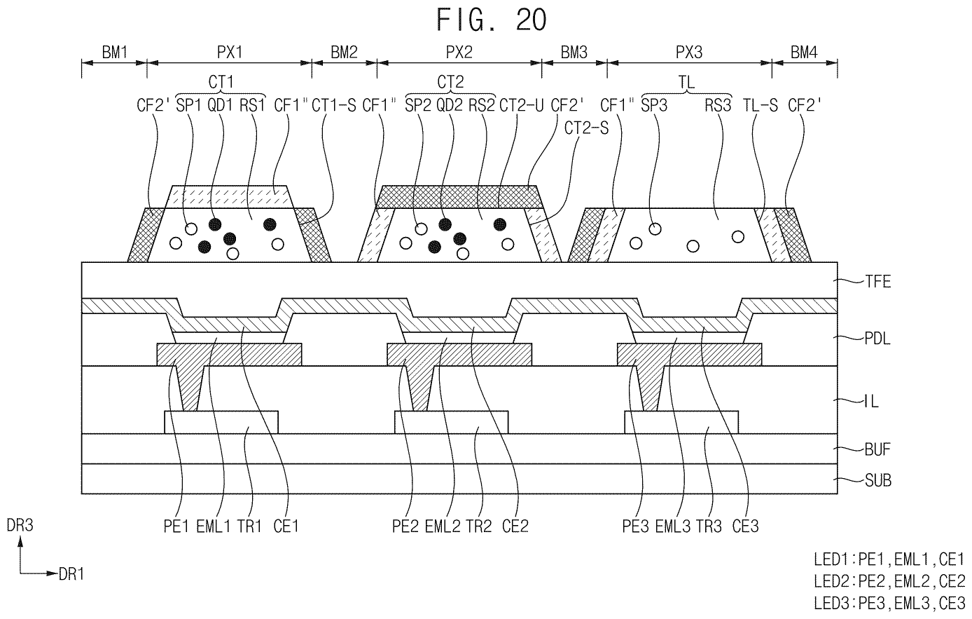

Referring to FIGS. 19 and 20, the second color filter layer CF2′ may be formed by removing a portion of the second preliminary color filter layer PCF2. The second color filter layer CF2′ may be formed to cover the second color conversion layer CT2. For example, the second color filter layer CF2′ may be formed to cover the upper surface CT2-U of the second color conversion layer CT2. For example, the second color filter layer CF2′ may be formed to cover the upper surface of the portion of the first color filter layer CF1″ covering the side surface CT2-S of the second color conversion layer CT2. In addition, the second color filter layer CF2′ may be formed to cover the first color conversion layer CT1. For example, the second color filter layer CF2′ may be formed to cover the side surface CT1-S of the first color conversion layer CT1. In addition, the second color filter layer CF2′ may cover the side surface of the portion of the first color filter layer CF1″ covering the side surface TL-S of the light transmitting layer TL.

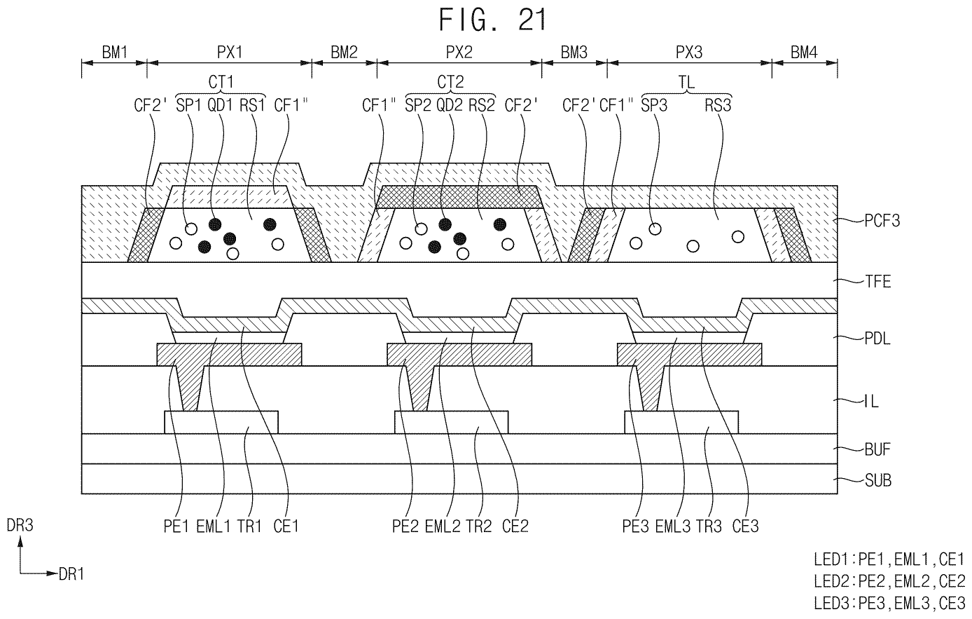

Referring to FIG. 21, the third preliminary color filter layer PCF3 may be formed on the first color conversion layer CT1, the second color conversion layer CT2, the light transmitting layer TL, and the encapsulation layer TFE. For example, the third preliminary color filter layer PCF3 may be formed to cover the first color conversion layer CT1, the second color conversion layer CT2, the light transmitting layer TL, the encapsulation layer TFE, the first color filter layer CF1″, and the second color filter layer CF2′.

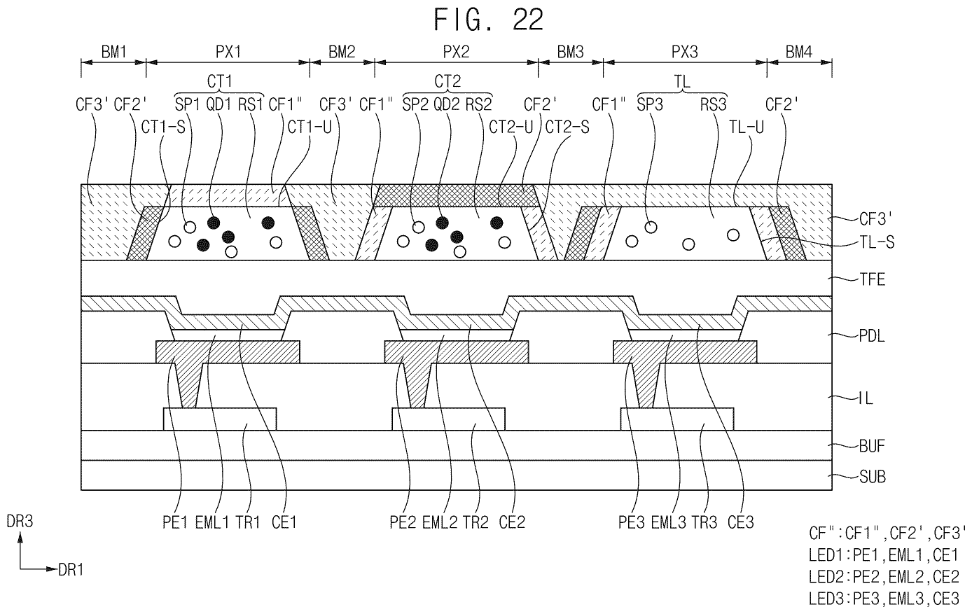

Referring to FIGS. 21 and 22, the third color filter layer CF3′ may be formed by removing a portion of the third preliminary color filter layer PCF3. For example, the third color filter layer CF3′ may be formed to cover the light transmitting layer TL. For example, the third color filter layer CF3′ may be formed to cover the upper surface TL-U of the light transmitting layer TL. In addition, the third color filter layer CF3′ may be formed to cover the upper surface of the portion of the first color filter layer CF1″ covering the side surface TL-S of the light transmitting layer TL. In addition, the third color filter layer CF3′ may be formed to cover the upper surface of the portion of the second color filter layer CF2′ covering the side surface of the first color filter layer CF1″.

The third color filter layer CF3′ may be formed in at least a portion of the first non-light emitting area BM1. For example, the third color filter layer CF3′ may be formed in an entirety of the first non-light emitting area BM1. The third color filter layer CF3′ may be formed in an entirety of at least a portion of the fourth non-light emitting area BM4. For example, the third color filter layer CF3′ may be entirely formed in the fourth non-light emitting area BM4.

The third color filter layer CF3′ may be formed in at least a portion of the second non-light emitting area BM2. For example, the third color filter layer CF3′ may be formed in an entirety of the second non-light emitting area BM2. For example, the third color filter layer CF3′ may be formed to cover the second color filter layer CF2′ covering the side surface CT1-S of the first color conversion layer CT1. In addition, the third color filter layer CF3′ may be formed to cover the side surface of the portion of the first color filter layer CF1″ covering the upper surface CT1-U of the first color conversion layer CT1.

The third color filter layer CF3′ may be formed in at least a portion of the third non-light emitting area BM3. For example, the third color filter layer CF3′ may be formed in an entirety of the third non-light emitting area BM3. For example, the third color filter layer CF3′ may be formed to cover the side surface of the portion of the first color filter layer CF1′ covering the side surface CT2-S of the second color conversion layer CT2. In addition, the third color filter layer CF3′ may be formed to cover the side surface of the portion of the second color filter layer CF2′ covering the upper surface CT2-U of the second color conversion layer CT2.

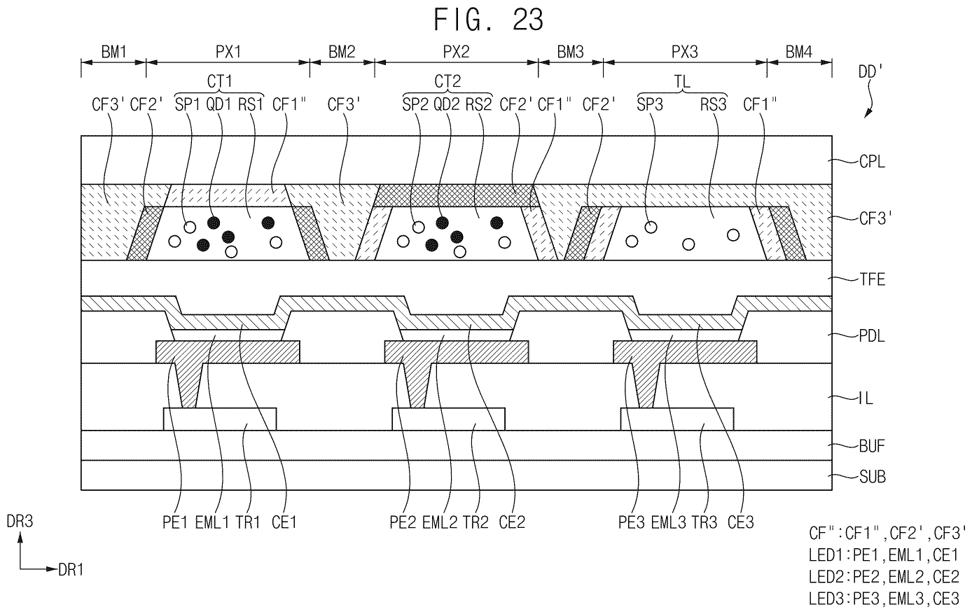

Referring to FIG. 23, the capping layer CPL may be formed on the color filter layer CF″. For example, the capping layer CPL may be formed to cover the first color filter layer CF1″, the second color filter layer CF2′, and the third color filter layer CF3′.

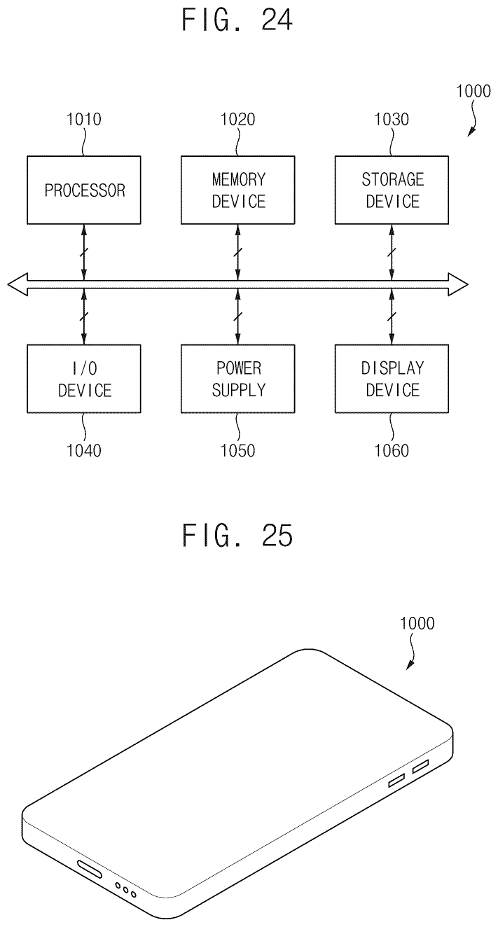

FIG. 24 is a block diagram illustrating an electronic device according to embodiments. FIG. 25 is a diagram illustrating an example in which the electronic device of FIG. 24 is implemented as a smart phone.

Referring to FIGS. 24 and 25, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 25, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first light emitting element disposed in a first pixel area;
a second light emitting element disposed in a second pixel area spaced apart from the first pixel area;
a first color conversion layer disposed on the first light emitting element;
a second color conversion layer disposed on the second light emitting element;
a first color filter layer covering the first color conversion layer;
a second color filter layer covering the second color conversion layer, and
a third color filter layer disposed in a first non-light emitting area between the first pixel area and the second pixel area,
wherein the third color filter layer is configured to selectively transmit a color light different from color lights selectively transmitted by the first color conversion layer and the second color conversion layer.

2. The display device of claim 1, wherein the first color filter layer covers an upper surface of the first color conversion layer and a side surface of the first color conversion layer.

3. The display device of claim 1, wherein the second color filter layer covers an upper surface of the second color conversion layer and extends to at least a portion of the first non-light emitting area.

4. The display device of claim 1, further comprising:
a third light emitting element disposed in a third pixel area spaced apart from the first pixel area and the second pixel area; and
a light transmitting layer disposed on the third light emitting element,
wherein the third color filter layer covers the light transmitting layer.

5. The display device of claim 4, wherein a portion of the first color filter layer covers a side surface of the light transmitting layer.

6. The display device of claim 5, wherein the third color filter layer is disposed in a portion of the first non-light emitting area.

7. The display device of claim 6, wherein the third color filter layer is disposed in at least a portion of a second non-light emitting area between the second pixel area and the third pixel area.

8. The display device of claim 7, wherein the third color filter layer is in contact with a side surface of the first color filter layer.

9. The display device of claim 8, wherein the third color filter layer covers an upper surface of the portion of the first color filter layer covering the side surface of the light transmitting layer.

10. The display device of claim 7, wherein the second color filter layer covers at least a portion of an upper surface of the third color filter layer.

11. The display device of claim 7, wherein the first color filter layer is disposed in an entirety of the first non-light emitting area.

12. The display device of claim 11, wherein the first color filter layer is disposed in an entirety of the second non-light emitting area.

13. The display device of claim 12, wherein the first color filter layer is in contact with a side surface of the second color conversion layer.

14. The display device of claim 1, further comprising:
a first low refractive index layer disposed between the first color conversion layer and the first color filter layer; and
a second low refractive index layer disposed between the second color conversion layer and the second color filter layer.

15. A display device comprising:
a first light emitting element disposed in a first pixel area;
a second light emitting element disposed in a second pixel area spaced apart from the first pixel area;
a third light emitting element disposed in a third pixel area spaced apart from the first pixel area and the second pixel area;
a first color conversion layer disposed on the first light emitting element;
a second color conversion layer disposed on the second light emitting element;
a light transmitting layer disposed on the third light emitting element;
a first color filter layer covering an upper surface of the first color conversion layer, a side surface of the second color conversion layer, and a side surface of the light transmitting layer;
a second color filter layer covering a side surface of the first color conversion layer, an upper surface of the second color conversion layer, and a side surface of the light transmitting layer; and
a third color filter layer covering an upper surface of the light transmitting layer.

16. The display device of claim 15, wherein the third color filter layer is further disposed in a first non-light emitting area between the first pixel area and the second pixel area.

17. The display device of claim 16, wherein the third color filter layer covers a portion of the second color filter layer covering the side surface of the first color conversion layer.

18. The display device of claim 16, wherein the third color filter layer is further disposed in a second non-light emitting area between the second pixel area and the third pixel area.

19. The display device of claim 18, wherein the third color filter layer covers a portion of the first color filter layer covering the side surface of the second color conversion layer.

20. The display device of claim 19, wherein the third color filter layer covers a side surface of a portion of the first color filter layer covering the upper surface of the first color conversion layer and a side surface of a portion of the second color filter layer covering the upper surface of the second color conversion layer.

21. The display device of claim 20, wherein the third color filter layer covers an upper surface of a portion of the first color filter layer covering the side surface of the light transmitting layer and an upper surface of a portion of the second color filter layer covering the side surface of the light transmitting layer.

22. A method of manufacturing a display device comprising:
forming a first light emitting element in a first pixel area;
forming a second light emitting element in a second pixel area spaced apart from the first pixel area;
forming a third light emitting element in a third pixel area spaced apart from the first pixel area and the second pixel area;
forming a first color conversion layer on the first light emitting element;
forming a second color conversion layer on the second light emitting element;
forming a light transmitting layer on the third light emitting element;
forming a first color filter layer covering the first color conversion layer;
forming a second color filter layer covering the second color conversion layer; and
forming a third color filter layer covering the light transmitting layer and disposed in a first non-light emitting area between the first pixel area and the second pixel area.

23. The method of claim 22, wherein the forming of the first color filter layer includes:
forming a first preliminary color filter layer covering the first color conversion layer, the second color conversion layer, and the light transmitting layer; and
removing a portion of the first preliminary color filter layer to form the first color filter layer, which covers a side surface of the light transmitting layer, an upper surface of the first color conversion layer, and a side surface of the first color conversion layer.

24. The method of claim 22, wherein the forming of the second color filter layer includes:
forming a second preliminary color filter layer covering the first color conversion layer, the second color conversion layer, and the light transmitting layer; and
removing a portion of the second preliminary color filter layer to form the second color filter layer, which covers an upper surface of the second color conversion layer.

25. The method of claim 22, wherein the forming of the third color filter layer includes:
forming a third preliminary color filter layer covering the first color conversion layer, the second color conversion layer, and the light transmitting layer; and
removing a portion of the third preliminary color filter layer to form the third color filter layer, which covers the light transmitting layer, and is disposed in the first non-light emitting area between the first pixel area and the second pixel area and a second non-light emitting area between the second pixel area and the third pixel area.

26. The method of claim 22, wherein the forming of the third color filter layer is performed before the forming the second color filter layer.

27. An electronic device comprising:
a first light emitting element disposed in a first pixel area;
a second light emitting element disposed in a second pixel area spaced apart from the first pixel area;
a first color conversion layer disposed on the first light emitting element;
a second color conversion layer disposed on the second light emitting element;
a first color filter layer covering the first color conversion layer;
a second color filter layer covering the second color conversion layer,
a third color filter layer disposed in a first non-light emitting area between the first pixel area and the second pixel area, and
a memory device configured to store data,
wherein the third color filter layer is configured to selectively transmit a color light different from color lights selectively transmitted by the first color conversion layer and the second color conversion layer.
